(19) United States
(12) Patent Application Publication
(10) Pub. No.: US 2025/0176310 A1
(43) Pub. Date: May 29, 2025

(54) DISPLAY DEVICE AND METHOD OF MANUFACTURING THE SAME

(71) Applicant: LG Display Co., Ltd., Seoul (KR)

(72) Inventors: Soyoung Lee, Seoul (KR); KwangSu Lim, Seoul (KR); YoungIn Jang, Seoul (KR); Junhyeok Lee, Seoul (KR)

(73) Assignee: LG Display Co., Ltd., Seoul (KR)

(21) Appl. No.: 18/936,801

(22) Filed: Nov. 4, 2024

(30) Foreign Application Priority Data
Nov. 24, 2023 (KR) 10-2023-0165978

(51) Int. Cl. H01L 33/00; H01L 25/075; H01L 33/20; H01L 33/38; H01L 33/62

(52) U.S. Cl. CPC H10H 20/01; H01L 25/0753; H10H 20/819; H10H 20/831; H10H 20/857

(57) ABSTRACT

According to another aspect of the present disclosure, a method of manufacturing a display device includes self-assembling a plurality of light emitting diodes on an assembling substrate; transferring the plurality of light emitting diodes which is self-assembled on the assembling substrate onto a donor; and transferring the plurality of light emitting diodes on the donor onto an adhesive layer of a display panel, the self-assembling of a plurality of light emitting diodes is a step of applying a voltage to a plurality of assembly electrodes to form an electric field and self-assembling a plurality of light emitting diodes on the plurality of assembly electrodes with the electric field.

### CROSS-REFERENCE TO RELATED APPLICATIONS

This application claims the priority of Korean Patent Application No. 10-2023-0165978 filed on Nov. 24, 2023, in the Korean Intellectual Property Office, the disclosure of which is incorporated herein by reference.

### BACKGROUND

### Technical Field

The present disclosure relates to a display device and a method of manufacturing the same, and more particularly to, a display device using a light emitting diode (LED) and a method of manufacturing the same.

### Discussion of the Related Art

As display devices which are used for a monitor of a computer, a television, a cellular phone, or the like, there are an organic light emitting display (OLED) device, which is a self-emitting device, a liquid crystal display (LCD) device, which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

Accordingly, embodiments of the present disclosure are directed to a display device and a method of manufacturing the same that substantially obviate one or more of the problems due to limitations and disadvantages of the related art.

An aspect of the present disclosure is to provide a display device which minimizes a luminance deviation according to a viewing angle and a method of manufacturing a display device.

Another aspect of the present disclosure is to provide a display device with an improved luminance and a method of manufacturing a display device.

Still another aspect of the present disclosure is to provide a display device which suppresses the transferring of a defective light emitting diode and a method of manufacturing a display device.

Still another aspect of the present disclosure is to provide a display device in which a light emitting diode and an electrode can be connected in various directions and a method of manufacturing a display device.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, an assembling substrate comprises an assembly substrate; a plurality of first assembly lines disposed on the assembly substrate; a plurality of second assembly lines which is disposed on the assembly substrate and is alternately disposed with the plurality of first assembly lines; and an organic layer which is disposed on the plurality of first assembly lines and the plurality of second assembly lines and includes a plurality of openings, and the plurality of openings includes a plurality of first oval openings and a plurality of second oval openings having a different planar shape from the plurality of first oval openings, a plurality of unit areas configured by the plurality of first oval openings and the plurality of second oval openings is defined on the assembly substrate, and in at least one unit area, among the plurality of unit areas, a long axis direction of the plurality of openings is different from a long axis direction of the plurality of openings in an adjacent unit area.

In another aspect, a method of manufacturing a display device comprises self-assembling a plurality of light emitting diodes on an assembling substrate; transferring the plurality of light emitting diodes which is self-assembled on the assembling substrate onto a donor; and transferring the plurality of light emitting diodes on the donor onto an adhesive layer of a display panel, the self-assembling of a plurality of light emitting diodes is a step of applying a voltage to a plurality of assembly electrodes to form an electric field and self-assembling a plurality of light emitting diodes on the plurality of assembly electrodes with the electric field. The plurality of light emitting diodes includes a plurality of first oval light emitting diodes and a second oval light emitting diodes which has a different planar shape from that of the plurality of first oval light emitting diodes, the self-assembling of a plurality of light emitting diodes on an assembling substrate includes assembling at least a part of the first oval light emitting diodes in the different direction from the adjacent first oval light emitting diode, and assembling at least a part of the second oval light emitting diodes in the different direction from the adjacent second oval light emitting diode.

In another aspect, a display device comprises a substrate in which a plurality of pixels including a plurality of sub pixels is defined; and a plurality of light emitting diodes disposed in the plurality of pixels, the plurality of light emitting diodes includes a plurality of oval light emitting diodes, and in at least one pixel among the plurality of pixels, a long axis of the plurality of oval light emitting diodes may be disposed in a different direction from a long axis of the plurality of oval light emitting diodes which is disposed on an adjacent pixel. Accordingly, the plurality of light emitting diodes is disposed in various directions to minimize the visibility of color and luminance stains from being visible from the display panel.

Other detailed matters of the exemplary embodiments are included in the detailed description and the drawings.

According to the present disclosure, an emission area of a light emitting diode can be expanded.

According to the present disclosure, only a light emitting diode which is not broken is transferred to improve a production efficiency.

According to the present disclosure, during the self-assembling, even though the plurality of light emitting diodes is self-assembled in various directions, the electrode can be easily connected.

According to the present disclosure, during the self-assembling, the plurality of light emitting diodes is self-assembled in various directions so that the visibility of color and luminance stains in a display panel may be minimized.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is an enlarged plan view of a display device according to an exemplary embodiment of the present disclosure;

FIG. 4 is a cross-sectional view of a display device according to an exemplary embodiment of the present disclosure;

FIGS. 5A to 5C are views for explaining a plurality of light emitting diodes of a display device according to an exemplary embodiment of the present disclosure;

FIG. 6 is a cross-sectional view of a display device according to another exemplary embodiment of the present disclosure;

FIGS. 7A to 7C are views for explaining a plurality of light emitting diodes of a display device according to another exemplary embodiment of the present disclosure;

FIGS. 8A to 8C are views for explaining a plurality of light emitting diodes of a display device according to still another exemplary embodiment of the present disclosure;

FIG. 9 is a plan view of an assembling substrate according to an exemplary embodiment of the present disclosure;

FIG. 10A is an enlarged plan view of an assembling substrate of a display device according to an exemplary embodiment of the present disclosure;

FIG. 10B is a cross-sectional view of a display device taken along Xb-Xb′ of FIG. 10A;

FIGS. 11A to 11H are process diagrams for explaining a method of manufacturing a display device according to an exemplary embodiment of the present disclosure; and

FIG. 12 is a plan view of an assembling substrate according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

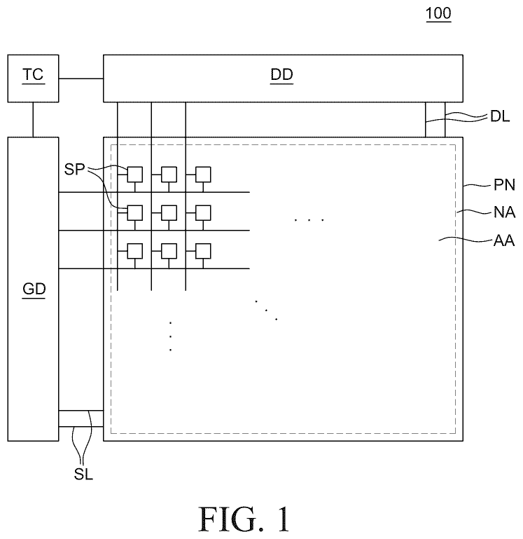

FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel PX. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of signal lines which transmits various signals to the plurality of sub pixels SP is disposed. For example, the plurality of signal lines includes a plurality of data lines DL which supplies a data voltage to each of the plurality of sub pixels SP, a plurality of scan lines which supplies a gate voltage to each of the plurality of sub pixels SP, and the like. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed. The non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and may be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel may be increased.

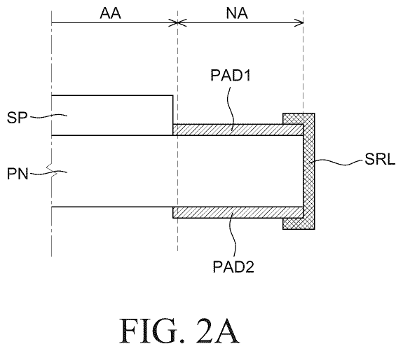

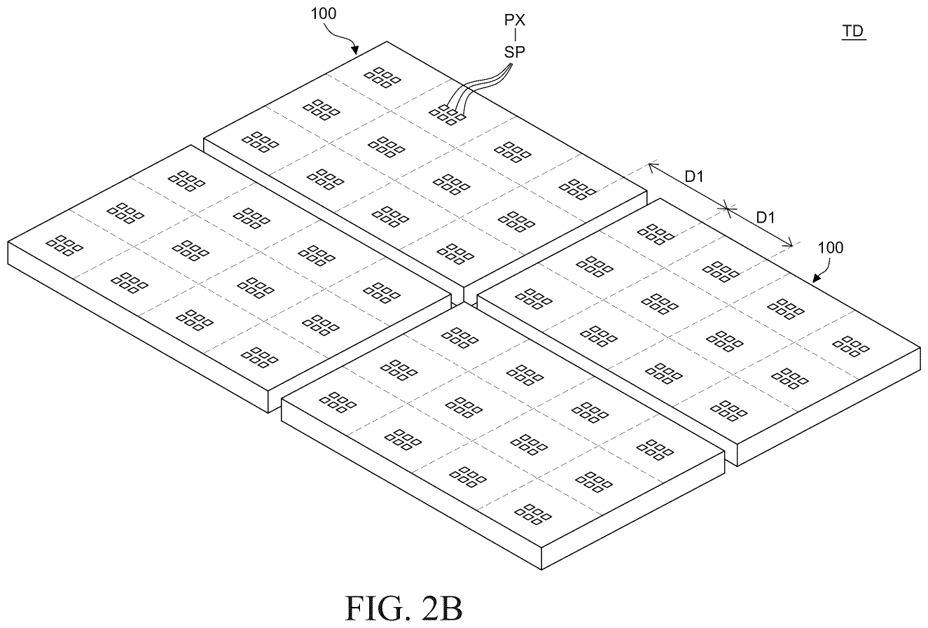

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

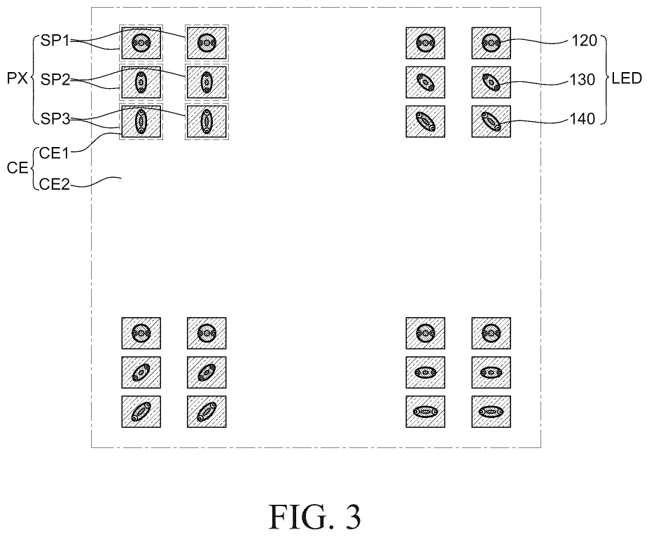

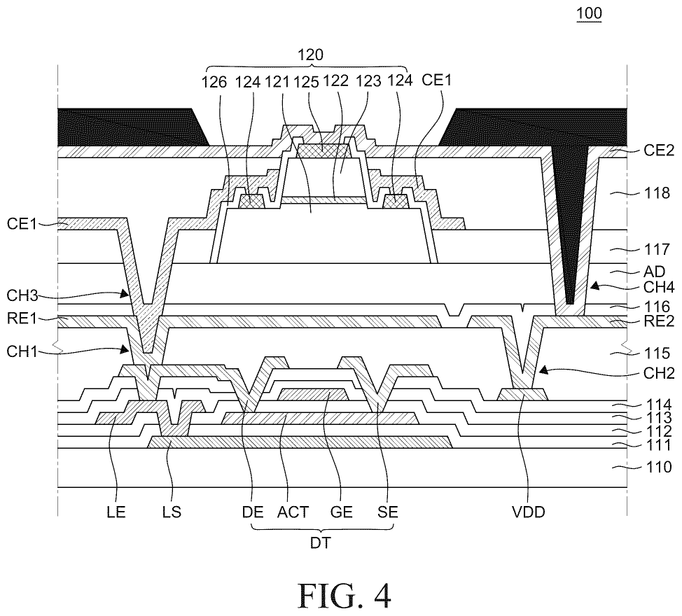

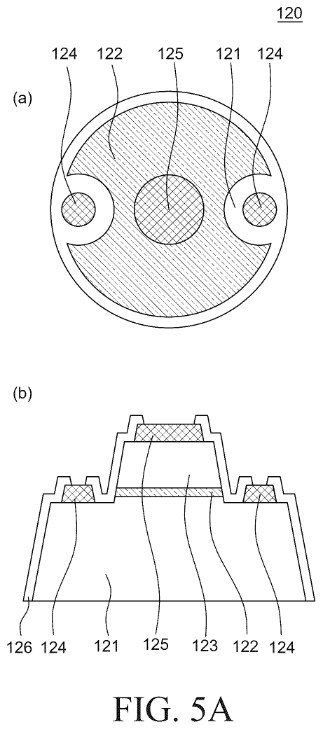

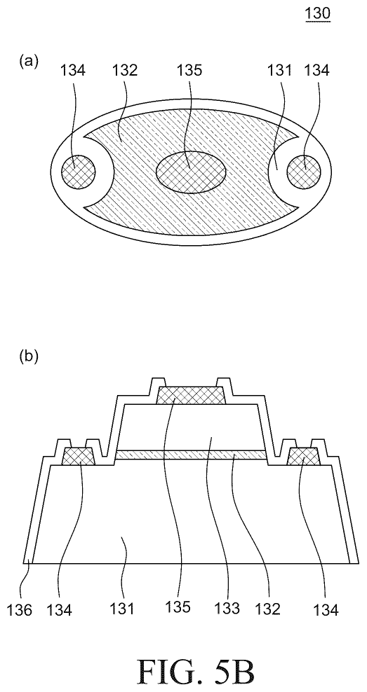

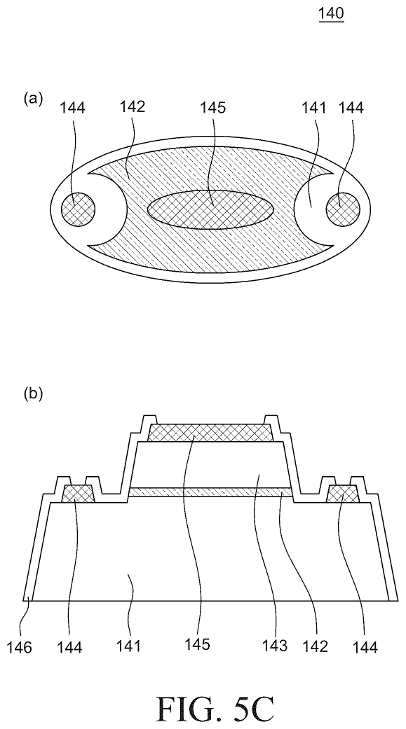

FIG. 3 is a schematic enlarged plan view of a display device according to an exemplary embodiment of the present disclosure. FIG. 4 is a cross-sectional view of a display device according to an exemplary embodiment of the present disclosure. FIGS. 5A to 5C are views for explaining a plurality of light emitting diodes of a display device according to an exemplary embodiment of the present disclosure. For the convenience of illustration, the hatching of the second connection electrode CE2 is omitted in FIG. 3.

First, referring to FIG. 3, the display panel PN includes a plurality of pixels PX which is formed by a plurality of sub pixels SP. Each of the plurality of sub pixels SP includes a light emitting diode LED and a pixel circuit to independently emit light. One pixel PX may include one or more first sub pixels SP1, one or more second sub pixels SP2, and one or more third sub pixels SP3. For example, one pixel PX may include two first sub pixels SP1, two second sub pixels SP2, and two third sub pixels SP3. At this time, the first sub pixel SP1 is a red sub pixel, the second sub pixel SP2 is a green sub pixel, and the third sub pixel SP3 is a blue sub pixel, but they are not limited thereto.

Referring to FIGS. 5A to 5C together, the plurality of light emitting diodes LED includes a first light emitting diode 120, a second light emitting diode 130, and a third light emitting diode 140. The first light emitting diode 120 may be disposed in the first sub pixel SP1, the second light emitting diode 130 may be disposed in the second sub pixel SP2, and the third light emitting diode 140 may be disposed in the third sub pixel SP3. For example, the first light emitting diode 120 may be a red light emitting diode, the second light emitting diode 130 may be a green light emitting diode, and the third light emitting diode 140 may be a blue light emitting diode, but the present disclosure is not limited thereto.

Referring to FIG. 3, the first sub pixel SP1, the second sub pixel SP2, and the third sub pixel SP3 in which the first light emitting diode 120, the second light emitting diode 130, and the third light emitting diode 140 are disposed may form one pixel PX. At this time, one pair of first sub pixels SP1 in which one pair of first light emitting diodes 120 is disposed, one pair of second sub pixels SP2 in which one pair of second light emitting diodes 130 is disposed, and one pair of third sub pixels SP3 in which one pair of third light emitting diodes 140 is disposed may configure one pixel PX. However, the present disclosure is not limited thereto.

In the meantime, each of the plurality of second light emitting diodes 130 and the plurality of third light emitting diodes 140 may be disposed in various directions on the display panel PN, and for example, may be disposed in a random direction. For example, in one pixel PX, long axes of the plurality of second light emitting diodes 130 and the plurality of third light emitting diodes 140 may be disposed along a row direction. In another pixel PX, long axes of the plurality of second light emitting diodes 130 and the plurality of third light emitting diodes 140 may be disposed along a column direction. Further, in still another pixel PX, long axes of the plurality of second light emitting diodes 130 and the plurality of third light emitting diodes 140 may be disposed along a direction between the row direction and the column direction. Therefore, in one pixel PX, a long axis of each of the second light emitting diode 130 and the third light emitting diode 140 may be disposed in a different direction from that of a long axis of each of the second light emitting diode 130 and the third light emitting diode 140 disposed in an adjacent pixel PX. In the meantime, the arrangement of the plurality of light emitting diodes LED illustrated in FIG. 3 is illustrated for the convenience of description, but the present disclosure is not limited thereto. The long axes of the plurality of second light emitting diodes 130 and the plurality of third light emitting diodes 140 may be disposed in various directions and also in one pixel PX, long axes of the plurality of second light emitting diodes 130 and the plurality of third light emitting diodes 140 may be disposed in different directions.

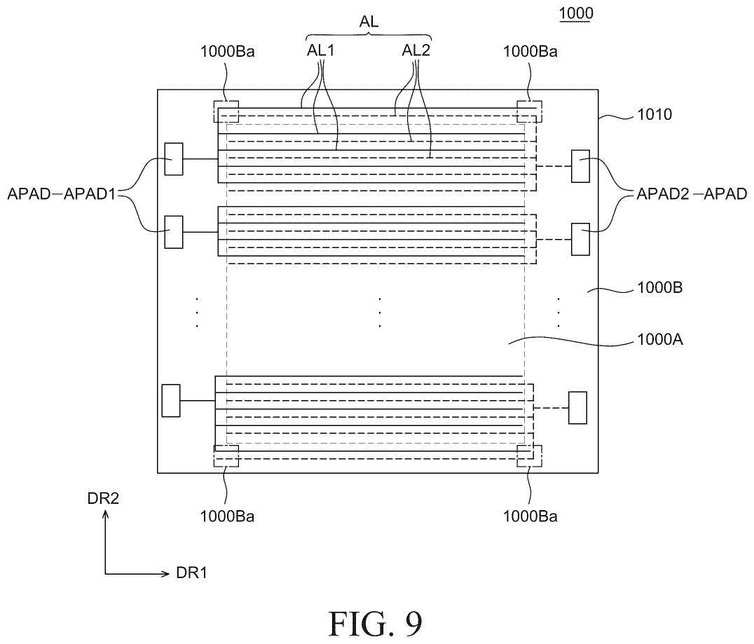

The arrangement of the plurality of light emitting diodes LED will be described in detail below with reference to FIGS. 9 to 11G.

Next, referring to FIG. 4 together, in each of the plurality of sub pixels SP of the display panel PN of the display device 100 according to the exemplary embodiment of the present disclosure, a substrate 110, a buffer layer 111, a gate insulating layer 112, a first interlayer insulating layer 113, a second interlayer insulating layer 114, a first planarization layer 115, a passivation layer 116, an adhesive layer AD, a second planarization layer 117, a third planarization layer 118, a driving transistor DT, a light emitting diode LED, a plurality of reflective electrodes RE, a plurality of connection electrodes CE, a light shielding layer LS, and an auxiliary electrode LE are disposed.

First, the substrate 110 is a component for supporting various components included in the display device 100 and may be formed of an insulating material. For example, the substrate 110 may be formed of glass or resin. Further, the substrate 110 may be configured to include polymer or plastics or may be formed of a material having flexibility.

The light shielding layer LS is disposed in each of the plurality of sub pixels SP on the substrate 110. The light shielding layer LS blocks light incident onto an active layer ACT of the driving transistor DT to be described below, below the substrate 110. Light which is incident onto the active layer ACT of the driving transistor DT is blocked by the light shielding layer LS to minimize a leakage current.

The buffer layer 111 is disposed on the substrate 110 and the light shielding layer LS. The buffer layer 111 may reduce permeation of moisture or impurities through the substrate 110. For example, the buffer layer 111 may be configured by a single layer or a double layer of silicon oxide SiOx or silicon nitride SiNx, but is not limited thereto. However, the buffer layer 111 may be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which the source electrode SE and the drain electrode DE are each connected to the active layer ACT is formed. The first interlayer insulating layer 113 and the second interlayer insulating layer 114 are insulating layers for protecting a component below the first interlayer insulating layer 113 and the second interlayer insulating layer 114 and may be configured by a single layer or a double layer of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, that is, a plurality of insulating layers is disposed between the gate electrode GE, and the source electrode SE and the drain electrode DE. However, only one insulating layer may be disposed between the gate electrode GE, and the source electrode SE and the drain electrode DE, but is not limited thereto.

As illustrated in the drawings, when a plurality of insulating layers, such as the first interlayer insulating layer 113 and the second interlayer insulating layer 114, is disposed between the gate electrode GE, and the source electrode SE and the drain electrode DE, an electrode may be further formed between the first interlayer insulating layer 113 and the second interlayer insulating layer 114. The additionally formed electrode may form a capacitor with the other configuration disposed below the first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE and the drain electrode DE through the auxiliary electrode LE so as not to operate as a floating gate. Therefore, fluctuation of a threshold voltage of the driving transistor DT caused by the floated light shielding layer LS may be minimized. Even though in the drawing, it is described that the light shielding layer LS is connected to the source electrode SE, the light shielding layer LS may also be connected to the drain electrode DE, but is not limited thereto.

The power line VDD is disposed on the second interlayer insulating layer 114. The power line VDD is electrically connected to the light emitting diode LED together with the driving transistor DT to allow the light emitting diode LED to emit light. The power line VDD may be configured by a conductive material such as copper (Cu), aluminum (Al), molybdenum (Mo), nickel (Ni), titanium (Ti), chrome (Cr), or an alloy thereof, but is not limited thereto.

The first planarization layer 115 is disposed on the driving transistor DT and the power line VDD. The first planarization layer 115 may planarize an upper portion of the substrate 110 on which the driving transistor DT is disposed. The first planarization layer 115 may be configured by a single layer or a double layer, and for example, may be formed of photoresist or an acrylic organic material, but is not limited thereto.

A plurality of reflective electrodes RE which is spaced apart from each other is disposed on the first planarization layer 115. The plurality of reflective electrodes RE electrically connects the light emitting diode LED to the power line VDD and the driving transistor DT and at the same time, may serve as a reflector which reflects light emitted from the light emitting diode LED to the upper portion of the light emitting diode LED. The plurality of reflective electrodes RE is formed of a conductive material having the excellent reflecting property to reflect light emitted from the light emitting diode LED toward the upper portion of the light emitting diode LED.

The plurality of reflective electrodes RE includes a first reflective electrode RE1 and a second reflective electrode RE2. The first reflective electrode RE1 may electrically connect the driving transistor DT and the light emitting diode LED. The first reflective electrode RE1 may be connected to the source electrode SE or the drain electrode DE of the driving transistor DT through a first contact hole CH1 formed in the first planarization layer 115. The first reflective electrode RE1 may be electrically connected to the first electrode and the first semiconductor layer of the light emitting diode LED through a first connection electrode CE1 to be described below.

The second reflective electrode RE2 may electrically connect the power line VDD and the light emitting diode LED. The second reflective electrode RE2 may be connected to the power line VDD through a second contact hole CH2 formed in the first planarization layer 115 and may be electrically connected to p-type electrodes 125, 135, and 145 and p-type semiconductor layers 123, 133, and 143 of the light emitting diode LED through a second connection electrode CE2 to be described below.

The passivation layer 116 is disposed on the plurality of reflective electrodes RE. In the passivation layer 116, a third contact hole CH3 through which the first connection electrode CE1 is connected to the first reflective electrode RE1 and a fourth contact hole CH4 through which the second connection electrode CE2 is connected to the second reflective electrode RE2 are disposed. The passivation layer 116 is an insulating layer which protects components below the passivation layer 116 and may be configured by a single layer or a double layer of silicon oxide SiOx or silicon nitride SiNx, but is not limited thereto.

The adhesive layer AD is disposed on the plurality of reflective electrodes RE. The adhesive layer AD is coated on the entire substrate 110 to fix the light emitting diode LED disposed on the adhesive layer AD. For example, the adhesive layer AD may be selected from any one of adhesive polymer, epoxy resist, UV resin, polyimide, acrylate, urethane, and polydimethylsiloxane (PDMS), but is not limited thereto.

The plurality of light emitting electrodes LED is disposed in each of the plurality of sub pixels SP on the adhesive layer AD. The plurality of light emitting diodes LED is an element which emits light by a current and may include a light emitting diode LED which emits red light, green light, blue light, and the like and may implement various colored light including white by a combination thereof. For example, the plurality of light emitting diodes LED may be a light emitting diode (LED) or a micro LED, but is not limited thereto.

Referring to FIGS. 4 and 5A together, the first light emitting diode 120 includes a first n-type semiconductor layer 121, a first emission layer 122, a first p-type semiconductor layer 123, a first n-type electrode 124, a first p-type electrode 125, and a first encapsulation layer 126.

The first n-type semiconductor layer 121 is disposed on the adhesive layer AD and the first p-type semiconductor layer 123 is disposed on the first n-type semiconductor layer 121. The first n-type semiconductor layer 121 and the first p-type semiconductor layer 123 may be formed by doping n-type and p-type impurities into a specific material. For example, the first n-type semiconductor layer 121 and the first p-type semiconductor layer 123 may be layers doped with n-type and p-type impurities into a material such as gallium nitride (GaN), indium aluminum phosphide (InAlP), or gallium arsenide (GaAs), respectively. The p-type impurity may be magnesium (Mg), zinc (Zn), beryllium (Be), and the like, and the n-type impurity may be silicon (Si), germanium, tin (Sn), and the like, but is not limited thereto.

The first emission layer 122 is disposed between the first n-type semiconductor layer 121 and the first p-type semiconductor layer 123. The first emission layer 122 is supplied with holes and electrons from the first n-type semiconductor layer 121 and the first p-type semiconductor layer 123 to emit light. The first emission layer 122 may be formed by a single layer or a multi-quantum well (MQW) structure, and for example, may be formed of indium gallium nitride (InGaN) or gallium nitride (GaN), but is not limited thereto.

Referring to FIG. 5A, the first emission layer 122 and the first p-type semiconductor layer 123 are disposed to be spaced apart from the first n-type electrode 124. At this time, a part of the first emission layer 122 and the first p-type semiconductor layer 123 which are opposite to the first n-type electrode 124 may be disposed along a circumference of the first n-type electrode 124. For example, as illustrated in FIG. 5A, when circular first n-type electrodes 124 are disposed on both ends of the first n-type semiconductor 121, the first emission layer 122 and the first p-type semiconductor layer 123 may have concave curved patterns corresponding to the first n-type electrodes 124 on both ends of the first n-type semiconductor layer 121. In the meantime, on an end portion of the first n-type semiconductor layer 121 in which the first n-type electrode 124 is not disposed, the first emission layer 122 and the first p-type semiconductor layer 123 may be disposed along a circumference of the first n-type semiconductor layer 121. Therefore, in an area excluding the concave curved patterns of the first emission layer 122 and the first p-type semiconductor layer 123, the first emission layer 122 and the first p-type semiconductor layer 123 may have a convex curved shape along the circumference of the first n-type semiconductor layer 121.

Two or more first n-type electrodes 124 are disposed on the first n-type semiconductor layer 121. The first n-type electrode 124 is an electrode which electrically connects the driving transistor DT and the first n-type semiconductor layer 121. The first n-type electrode 124 may be disposed on a top surface of the first n-type semiconductor layer 121 which is exposed from the first emission layer 122 and the first p-type semiconductor layer 123. For example, the first n-type electrode 124 may be disposed to be adjacent to both end portions of a top surface of the first n-type semiconductor 121 having a circular planar shape. A planar shape of the first n-type electrode 124 may be a circular and/or oval shape. The first n-type electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first p-type electrode 125 is disposed on the first p-type semiconductor layer 123. The first p-type electrode 125 may be disposed on the top surface of the first p-type semiconductor layer 123. A planar shape of the first p-type electrode 125 may be a circular and/or oval shape. The first p-type electrode 125 is an electrode which electrically connects the power line VDD and the first p-type semiconductor layer 123. The first p-type electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the first encapsulation layer 126 which encloses the first n-type semiconductor layer 121, the first emission layer 122, the first p-type semiconductor layer 123, the first n-type electrode 124, and the first p-type electrode 125 is disposed. The first encapsulation layer 126 is formed of an insulating material to protect the first n-type semiconductor layer 121, the first emission layer 122, and the first p-type semiconductor layer 123. In the first encapsulation layer 126, a contact hole which exposes the first n-type electrode 124 and the first p-type electrode 125 is formed to electrically connect the first connection electrode CE1 and the second connection layer CE2 to the first n-type electrode 124 and the first p-type electrode 125.

Referring to FIG. 5B, the second light emitting diode 130 includes a second n-type semiconductor layer 131, a second emission layer 132, a second p-type semiconductor layer 133, a second n-type electrode 134, a second p-type electrode 135, and a second encapsulation layer 136.

The second n-type semiconductor layer 131 is disposed on the adhesive layer AD and the second p-type semiconductor layer 133 is disposed on the second n-type semiconductor layer 131. The second n-type semiconductor layer 131 and the second p-type semiconductor layer 133 may be formed by doping n-type and p-type impurities into a specific material. For example, the second n-type semiconductor layer 131 and the second p-type semiconductor layer 133 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but is not limited thereto.

The second emission layer 132 is disposed between the second n-type semiconductor layer 131 and the second p-type semiconductor layer 133. The second emission layer 132 is supplied with holes and electrons from the second n-type semiconductor layer 131 and the second p-type semiconductor layer 133 to emit light. The second emission layer 132 may be formed by a single layer or a multi-quantum well (MQW) structure, and for example, may be formed of indium gallium nitride (InGaN), gallium nitride (GaN), or the like, but is not limited thereto.

Referring to FIG. 5B, the second emission layer 132 and the second p-type semiconductor layer 133 are disposed to be spaced apart from the second n-type electrode 134. At this time, a part of side surfaces of the second emission layer 132 and the second p-type semiconductor layer 133 which is opposite to the second n-type electrode 134 may be disposed along the circumference of the second n-type electrode 134. For example, as illustrated in FIG. 5B, when circular second n-type electrodes 134 are disposed on both ends of the second n-type semiconductor 131, the second emission layer 132 and the second p-type semiconductor layer 133 may have concave curved patterns corresponding to the second n-type electrodes 134 on both ends of the second n-type semiconductor layer 131. In the meantime, on an end portion of the second n-type semiconductor layer 131 in which the second n-type electrode 134 is not disposed, the second emission layer 132 and the second p-type semiconductor layer 133 may be disposed along a circumference of the second n-type semiconductor layer 131. Therefore, in an area excluding the concave curved patterns of the second emission layer 132 and the second p-type semiconductor layer 133, the second emission layer 132 and the second p-type semiconductor layer 133 may have a convex curved shape along the circumference of the second n-type semiconductor layer 131.

Two or more second n-type electrodes 134 are disposed on the second n-type semiconductor layer 131. The second n-type electrode 134 is an electrode which electrically connects the driving transistor DT and the second n-type semiconductor layer 131. The second n-type electrode 134 may be disposed on a top surface of the second n-type semiconductor layer 131 which is exposed from the second emission layer 132 and the second p-type semiconductor layer 133. For example, the second n-type electrode 134 may be disposed to be adjacent to both end portions of the top surface of the second n-type semiconductor layer 131 in a long axis direction, on the top surface of the second n-type semiconductor layer 131 formed with an oval shape in plan view. A planar shape of the second n-type electrode 134 may be a circular and/or oval shape. The second n-type electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second p-type electrode 135 is disposed on the second p-type semiconductor layer 133. The second p-type electrode 135 may be disposed on the top surface of the second p-type semiconductor layer 133. A planar shape of the second p-type electrode 135 may be a circular and/or oval shape. The second p-type electrode 135 is an electrode which electrically connects the power line VDD and the second p-type semiconductor layer 133. The second p-type electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the second encapsulation layer 136 which encloses the second n-type semiconductor layer 131, the second emission layer 132, the second p-type semiconductor layer 133, the second n-type electrode 134, and the second p-type electrode 135 is disposed. The second encapsulation layer 136 is formed of an insulating material to protect the second n-type semiconductor layer 131, the second emission layer 132, and the second p-type semiconductor layer 133. In the second encapsulation layer 136, a contact hole which exposes the second n-type electrode 134 and the second p-type electrode 135 is formed to electrically connect the first connection electrode CE1 and the second connection electrode CE2 to the second n-type electrode 134 and the second p-type electrode 135.

Referring to FIG. 5C, the third light emitting diode 140 includes a third n-type semiconductor layer 141, a third emission layer 142, a second p-type semiconductor layer 133, a third n-type electrode 144, a third p-type electrode 145, and a third encapsulation layer 146.

The third n-type semiconductor layer 141 is disposed on the adhesive layer AD and the third p-type semiconductor layer 143 is disposed on the third n-type semiconductor layer 141. The third n-type semiconductor layer 141 and the third p-type semiconductor layer 143 may be formed by doping n-type and p-type impurities into a specific material. For example, the third n-type semiconductor layer 141 and the third p-type semiconductor layer 143 may be layers doped with n-type and p-type impurities into a material such as gallium nitride (GaN), indium aluminum phosphide (InAlP), or gallium arsenide (GaAs), respectively. The p-type impurity may be magnesium (Mg), zinc (Zn), beryllium (Be), and the like, and the n-type impurity may be silicon (Si), germanium, tin (Sn), and the like, but is not limited thereto.

The third emission layer 142 is disposed between the third n-type semiconductor layer 141 and the third p-type semiconductor layer 143. The third emission layer 142 is supplied with holes and electrons from the third n-type semiconductor layer 141 and the third p-type semiconductor layer 143 to emit light. The third emission layer 142 may be formed by a single layer or a multi-quantum well (MQW) structure, and for example, may be formed of indium gallium nitride (InGaN), gallium nitride (GaN), or the like, but is not limited thereto.

Referring to FIG. 5C, the third emission layer 142 and the third p-type semiconductor layer 143 are disposed to be spaced apart from the third n-type electrode 134. At this time, a part of side surfaces of the third emission layer 142 and the third p-type semiconductor layer 143 which is opposite to the third n-type electrode 144 may be disposed along the circumference of the third n-type electrode 144. For example, as illustrated in FIG. 5C, when circular third n-type electrodes 144 are disposed on both ends of the third n-type semiconductor layer 141, the third emission layer 142 and the third p-type semiconductor layer 143 may have concave curved patterns corresponding to the third n-type electrodes 144 on both ends of the third n-type semiconductor layer 141. In the meantime, on an end portion of the third n-type semiconductor layer 141 in which the third n-type electrode 144 is not disposed, the third emission layer 142 and the third p-type semiconductor layer 143 may be disposed along a circumference of the third n-type semiconductor layer 141. Therefore, in an area excluding the concave curved patterns of the third emission layer 142 and the third p-type semiconductor layer 143, the third emission layer 142 and the third p-type semiconductor layer 143 may have a convex curved shape along the circumference of the third n-type semiconductor layer 141.

The third n-type electrode 144 is disposed on the third n-type semiconductor layer 141. The third n-type electrode 144 is an electrode which electrically connects the driving transistor DT and the third n-type semiconductor layer 141. The third n-type electrode 144 may be disposed on an top surface of the third n-type semiconductor layer 141 which is exposed from the third emission layer 142 and the third p-type semiconductor layer 143. For example, the third n-type electrode 144 may be disposed to be adjacent to both end portions of the top surface of the third n-type semiconductor layer 141 in a long axis direction on the top surface of the third n-type semiconductor layer 141 formed with an oval planar shape. A planar shape of the third n-type electrode 144 may be a circular and/or oval shape. The third n-type electrode 144 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The third p-type electrode 145 is disposed on the third p-type semiconductor layer 143. The third p-type electrode 145 may be disposed on the top surface of the third p-type semiconductor layer 143. A planar shape of the third p-type electrode 145 may be a circular and/or oval shape. The third p-type electrode 145 is an electrode which electrically connects the power line VDD and the third p-type semiconductor layer 143. The third p-type electrode 145 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the third encapsulation layer 146 which encloses the third n-type semiconductor layer 141, the third emission layer 142, the third p-type semiconductor layer 143, the third n-type electrode 144, and the third p-type electrode 145 is disposed. The third encapsulation layer 146 is formed of an insulating material to protect the third n-type semiconductor layer 141, the third emission layer 142, and the third p-type semiconductor layer 143. In the third encapsulation layer 146, a contact hole which exposes the third n-type electrode 144 and the third p-type electrode 145 is formed to electrically connect the first connection electrode CE1 and the second connection layer CE2 to the third n-type electrode 144 and the third p-type electrode 145.

In the meantime, the first light emitting diode 120, the second light emitting diode 130, and the third light emitting diode 140 may be formed with different shapes. Each of the plurality of light emitting diodes LED commonly includes the n-type semiconductor layers 121, 131, and 141, the light emitting layers 122, 132, and 142, the p-type semiconductor layers 123, 133, and 143, the n-type electrodes 124, 134, and 144, the p-type electrodes 125, 135, and 145, and the encapsulation layers 126, 136, and 146. However, some components may have different shapes.

For example, the planar shape of the first n-type semiconductor layer 121 of the first light emitting diode 120 may be a circular shape. The planar shape of the second n-type semiconductor layer 131 of the second light emitting diode 130 may be an oval shape. The planar shape of the third n-type semiconductor layer 141 of the third light emitting diode 140 may be an oval shape. For example, a ratio of a long axis and a short axis of the third light emitting diode 140 may be different from a ratio of a long axis and a short axis of the second light emitting diode 130. A long axis of the third light emitting diode 140 may be longer than a long axis of the second light emitting diode 130 and a short axis of the third light emitting diode 140 may be shorter than a short axis of the second light emitting diode 130, but the present disclosure is not limited thereto.

In the display device 100 according to the exemplary embodiment of the present disclosure, the first light emitting diode 120 is configured as a circular light emitting diode, the second light emitting diode 130 is configured as a first oval light emitting diode, and the third light emitting diode 140 is configured as a second oval light emitting diode having a different planar shape from the second light emitting diode 130 to distinguish the plurality of light emitting diodes LED. For example, when the light emitting diode LED is self-assembled, the plurality of light emitting diodes LED is formed to have different shapes to be self-assembled in a position corresponding to each of the plurality of sub pixels SP. However, the shapes of the plurality of light emitting diodes LED are illustrative, so that they are not limited thereto.

The plurality of light emitting diodes LED may be disposed on the display panel PN in various directions. For example, a long axis direction of a second light emitting diode 130 in one pixel PX may be different from a long axis direction of a second light emitting diode 130 disposed in an adjacent pixel PX. Further, a long axis direction of a third light emitting diode 140 in one pixel PX may be different from a long axis direction of a third light emitting diode 140 disposed in an adjacent pixel PX.

In the meantime, the arrangement direction of the plurality of first light emitting diodes 120, the plurality of second light emitting diodes 130, and the plurality of third light emitting diodes 140 illustrated in FIG. 3 is just illustrative, but is not limited thereto. Even though in FIG. 3, it is illustrated that all the long axis directions of the second light emitting diodes 130 and the third light emitting diodes 140 disposed in the same pixel PX are disposed in the same direction, respectively, it is not limited thereto. Therefore, the long axis directions of the second light emitting diodes 130 and the third light emitting diodes 140 may be disposed differently in the same pixel PX, respectively.

The second planarization layer 117 and the third planarization layer 118 are disposed on the adhesive layer AD. The second planarization layer 117 overlaps a part of side surface portions of the plurality of light emitting diodes LED to fix and protect the plurality of light emitting diodes LED. Specifically, a thickness of the second planarization layer 117 may be smaller than the thicknesses of the n-type semiconductor layers 121, 131, and 141 of the plurality of light emitting diodes LED. For example, the top surface of the second planarization layer 117 may be disposed below the emission layers 122, 132, and 142.

The second planarization layer 117 may be disposed so as to enclose lower side surfaces of the n-type semiconductor layers 121, 131, and 141 extending from a bottom surface of the n-type semiconductor layers 121, 131, and 141 of the plurality of light emitting diodes LED on the adhesive layer AD.

In the meantime, during a process of separating the plurality of light emitting didoes LED from a wafer, a part of lower edges of the encapsulation layers 126, 136, and 146 of the plurality of light emitting diodes LED may be torn off. Further, when the first electrode CE1 is formed so as to enclose a side surface of the encapsulation layer 126, there may be a failure that the first connection electrode CE1 is disconnected in a torn part of the encapsulation layers 126, 136, and 146. Therefore, when the second planarization layer 117 encloses a lower side surface of the plurality of light emitting diodes LED before forming the first connection electrode CE1, a lower portion of the plurality of light emitting diodes LED may be spaced apart from the first connection electrode CE1 and the disconnection of the first connection electrode CE1 may be minimized.

The first connection electrode CE1 is disposed on the second planarization layer 117. The first connection electrode CE1 is an electrode which is disposed in each of the plurality of sub pixels SP to electrically connect the light emitting diode LED and the driving transistor DT. The first connection electrode CE1 may be connected to the first reflective electrode RE1 through the third contact hole CH3 formed in the second planarization layer 117, the adhesive layer AD, and the passivation layer 116. Accordingly, the first connection electrode CE1 may be electrically connected to any one of the source electrode SE and the drain electrode DE of the driving transistor DT through the first reflective electrode RE1. The first connection electrode CE1 may be connected to n-type electrodes 124, 134, and 144 of each of the plurality of light emitting diodes LED. Accordingly, the first connection electrode CE1 may electrically connect the driving transistor DT to the n-type electrodes 124, 134, and 144 and the n-type semiconductor layers 121, 131, and 141 of the plurality of light emitting diodes LED.

The first connection electrode CE1 may be disposed so as to enclose side surfaces of the plurality of light emitting diodes LED. When the display device 100 is manufactured, even though the second light emitting diode 130 and the third light emitting diode 140 are disposed in various directions, the first connection electrode CE1 may be connected to the n-type electrodes 124, 134, and 144 through the second planarization layer 117.

The third planarization layer 118 is disposed on the first connection electrode CE1 and the plurality of light emitting diodes LED. The third planarization layer 118 may planarize an upper portion of the substrate 110 in which the plurality of light emitting diodes LED is disposed and fix the plurality of light emitting diodes LED onto the substrate 110 together with the adhesive layer AD. The second planarization layer 117 and the third planarization layer 118 may be configured by a single layer or a double layer, and for example, may be formed of photoresist or an acrylic organic material, but is not limited thereto.

A top surface of the third planarization layer 118 may be disposed to be higher than at least the emission layers 122, 132, and 142 of the plurality of light emitting diodes LED and may be disposed to be at the same height as or lower than the top surface of the p-type semiconductor layers 123, 133, and 143. For example, the top surface of the third planarization layer 118 corresponding to the plurality of light emitting diodes LED is disposed between top surfaces of the emission layers 122, 132, and 142 and the p-type semiconductor layers 123, 133, and 143 or on the same planar as the top surface of the p-type semiconductor layers 123, 133, and 143. Therefore, when the display device 100 is manufactured, the second connection electrode CE2 may be connected only to the p-type semiconductor layers 123, 133, and 143 using the third planarization layer 118.

The second planarization layer 117 and the third planarization layer 118 may be configured by a single layer or a double layer, and for example, may be formed of photoresist or an acrylic organic material, but are not limited thereto. Even though in the present disclosure, it is described that the second planarization layer 117 and the third planarization layer 118 are disposed, the planarization layer may be formed by a single layer, but the present disclosure is not limited thereto.

The second connection electrode CE2 is disposed on the third planarization layer 118. The second connection electrode CE2 is an electrode for electrically connecting the light emitting diode LED and the power line VDD. The second connection electrode CE2 may be connected to the second reflective electrode RE2 through the fourth contact hole CH4 formed in the third planarization layer 118, the second planarization layer 117, the adhesive layer AD, and the passivation layer 116. Accordingly, the second connection electrode CE2 may be electrically connected to the power line VDD through the second reflective electrode RE2. The second connection electrode CE2 may be connected to the p-type electrodes 125, 135, and 145 of the plurality of light emitting diodes LED through a contact hole formed in the third planarization layer 118. Accordingly, the second connection electrode CE2 may electrically connect the power line VDD and the p-type electrodes 125, 135, and 145 and the p-type semiconductor layers 123, 133, and 143 of the plurality of light emitting diodes LED.

In the meantime, the first connection electrode CE1 which connects the driving transistor DT and the light emitting diode LED which are disposed in each of the plurality of sub pixels SP may be individually disposed in each of the plurality of sub pixels SP. The second connection electrodes CE2 which are disposed in each of the plurality of sub pixels SP to connect the power line VDD and the light emitting diode LED may be connected to each other. That is, a power voltage of the power line VDD is commonly applied to all the plurality of light emitting diodes LED of the plurality of sub pixels SP so that one second connection electrode CE2 may be disposed in all the plurality of sub pixels SP.

In the meantime, the display device 100 according to the exemplary embodiment of the present disclosure may be manufactured by transferring the plurality of self-assembled light emitting diodes LED using the donor 300 onto the display panel PN from the assembling substrate 200 after self-assembling the plurality of light emitting diodes LED on a separate assembling substrate.

In the meantime, the viewing angle luminance characteristic of the plurality of light emitting diodes may be affected by a shape of the light emitting diode. For example, the viewing angle luminance deviation may be caused according to the shapes of the plurality of electrodes disposed in the plurality of light emitting diodes and the plurality of semiconductor layers. For example, when an angle, a position, a width, and a size of the plurality of electrodes and the plurality of semiconductor layers are changed, luminance from various viewing angles may vary. Accordingly, the viewing angle luminance may be changed according to the shape deviation of each of the plurality of light emitting diodes.

For example, when light generated from the light emitting diode travels to the side surface direction of the light emitting diode, the traveling direction of the light may be changed on the side surface of the light emitting diode. Specifically, the luminance distribution according to the viewing angle of the light emitting diode may vary depending on an inclination angle of an area of the light emitting diode called a mesa unit, that is, a side surface of the second semiconductor layer and the active layer.

The mesa unit of the light emitting diode may be formed by a mesa-etching process and an inclined surface of the mesa unit of the light emitting diode may be formed by the mesa-etching process. In the meantime, after the mesa-etching process, various processes for forming the light emitting diode are performed and the mesa unit of the light emitting diode may be exposed to various processes. For example, after the mesa-etching process, an isolation process of etching a wafer and a semiconductor layer disposed on the wafer to separate the light emitting diode may be performed. At this time, the isolation process refers to a process of etching an area corresponding to an outer peripheral area of the light emitting diode to separate the light emitting diode from the wafer. Therefore, the etching process which is performed in the isolation process is performed on an area excluding the mesa unit. However, when there is a process deviation, the mesa unit may be exposed to the isolation process. For example, when the photoresist serves as a mask, one side of the mesa unit may be covered by the photoresist by the process error but the other side of the mesa unit may be exposed due to a difference of an area covered by the photoresist. Therefore, the mesa unit which is not covered by the photoresist due to the process deviation of the photoresist may be etched together with the wafer and the semiconductor layer disposed on the wafer. In this case, an inclination angle of the inclined surface of the mesa unit exposed by the isolation process may he different from an inclination angle of the inclined surface of the mesa unit covered by the photoresist and there may be a deviation in the inclination angle of the inclined surface of the mesa unit.

Specifically, in a structure in which the plurality of light emitting diodes is asymmetric, a variation range of the viewing angle luminance according to the shape deviation of the light emitting diode may be more significant. For example, a variation range of the viewing angle luminance according to the inclination angle deviation of the mesa unit in a light emitting diode having an asymmetric shape may be larger than a variation range of the viewing angle luminance according to the inclination angle deviation of the mesa unit in a light emitting diode having a symmetric shape.

Further, when the light emitting diode is formed to have an asymmetric shape having a long axis and a short axis, with the same process error, an inclination angle deviation of the mesa unit generated in the long axis direction of the light emitting diode may be different from an inclination angle deviation of the mesa unit generated in the short axis direction of the light emitting diode. Therefore, when the plurality of light emitting diodes is formed to have an oval shape, a viewing angle luminance characteristic in the short axis direction of the light emitting diode may be different from a viewing angle luminance characteristic in the long axis direction.

In the meantime, on the display panel, all the plurality of light emitting diodes may be disposed to be aligned in the same direction. For example, when the plurality of light emitting diodes is formed to have an oval shape, all the long axis directions of the plurality of light emitting diodes may be disposed along one same direction. Therefore, the luminance characteristic in a corresponding direction may be different from the luminance characteristic in the other direction, on the display panel. Therefore, when all the plurality of light emitting diodes is aligned in the same direction, the luminance asymmetric characteristic may be visible in the display device due to the luminance asymmetric characteristic of the plurality of light emitting diodes.

Accordingly, in the display device 100 according to the exemplary embodiment of the present disclosure, the plurality of light emitting diodes LED may be disposed in various directions. For example, long axes of the second light emitting diode 130 and the third light emitting diode 140 may be disposed in different directions in every pixel PX, respectively. Therefore, even though the plurality of light emitting diodes LED is formed to have an asymmetric shape, the plurality of light emitting diodes LED is disposed in various directions in the display panel PN so that the viewing angle deviation and the luminance deviation generated in a specific direction may be mitigated. Accordingly, in the display device 100 according to the exemplary embodiment of the present disclosure, the plurality of light emitting diodes LED is aligned in various directions to minimize a color difference and a stain caused by the viewing angle change and improve a color uniformity.

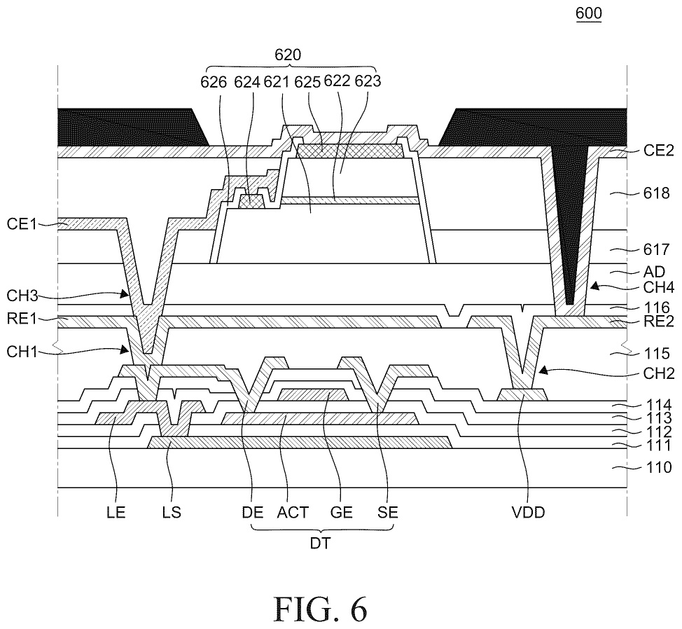

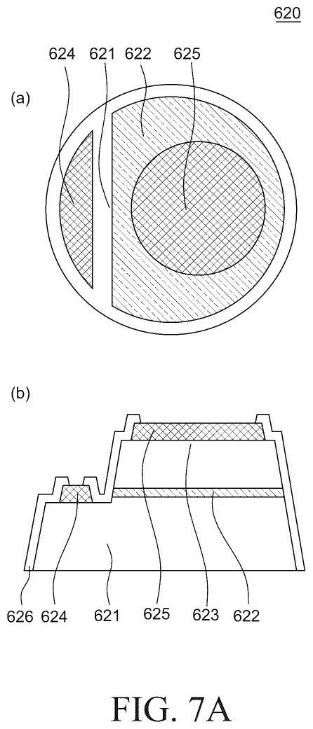

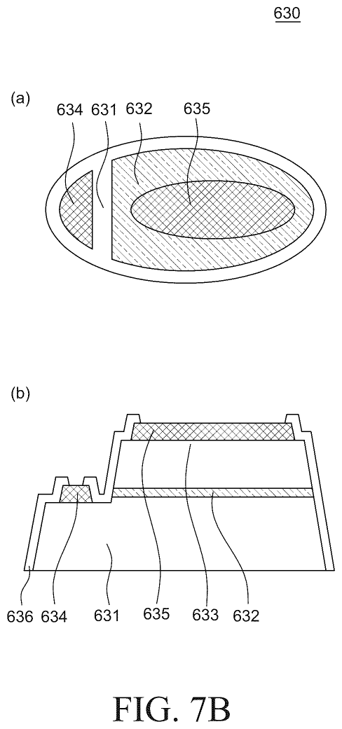

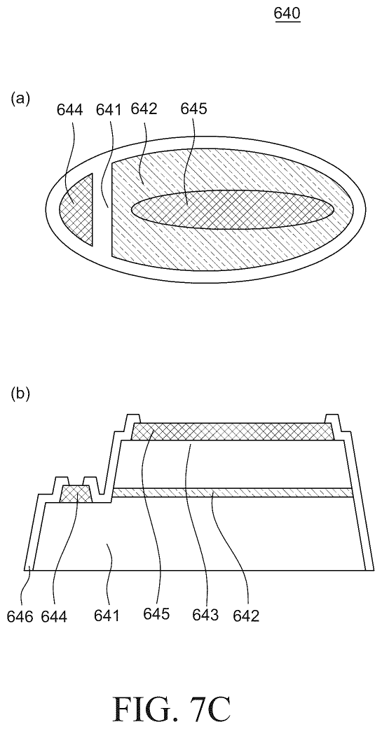

FIG. 6 is a cross-sectional view of a display device according to another exemplary embodiment of the present disclosure. FIGS. 7A to 7C are views for explaining a plurality of light emitting diodes of a display device according to another exemplary embodiment of the present disclosure. In a display device 600 of FIGS. 6, 7A to 7C, only a plurality of light emitting diodes LED, a second planarization layer 617, a third planarization layer 618, and a second connection electrode CE2 are different from those of the display device 100 of FIGS. 1 to 5C. Other configurations are substantially the same so that a redundant description will be omitted.

Referring to FIGS. 6 and 7A together, a first light emitting diode 620 includes a first n-type semiconductor layer 621, a first emission layer 622, a first p-type semiconductor layer 623, a first n-type electrode 624, a first p-type electrode 625, and a first encapsulation layer 626.

The first emission layer 622 and the first p-type semiconductor layer 623 are disposed on the first n-type semiconductor layer 621. The first n-type electrode 624 is disposed on one end portion of the first n-type semiconductor layer 621 and the first p-type electrode 625 is disposed on the other end portion of the first n-type semiconductor layer 621.

All the planar shapes of the first n-type semiconductor layer 621 of the first light emitting diode 620 may be a circular shape.

A planar shape of the first n-type electrode 624 may correspond to a partial shape of a circle. For example, a side surface of the first n-type electrode 624 adjacent to one end portion of the first n-type semiconductor layer 621 may be formed of a curved surface corresponding to the side surface of the first n-type semiconductor layer 621. In addition, a side surface of the first n-type electrode 624 adjacent to the other end portion of the first n-type semiconductor layer 621 may be formed by a plane which connects the side surface of the curved first n-type electrode 624.

The first emission layer 622 and the first p-type semiconductor layer 623 are disposed to be spaced apart from the first n-type electrode 624. At this time, the first emission layer 622 and the first p-type semiconductor layer 623 may be disposed along a circumference of the first n-type electrode 624. For example, as illustrated in FIG. 7A, when a semicircular first n-type electrode 624 is disposed in one end portion of the first n-type semiconductor layer 621, side surfaces of the first emission layer 622 and the first p-type semiconductor layer 623 which are opposite to the first n-type electrode 624 may be formed by a plane. In the meantime, on an end portion of the first n-type semiconductor layer 621 in which the first n-type electrode 624 is not disposed, the first emission layer 622 and the first p-type semiconductor layer 623 may be disposed along a circumference of the first n-type semiconductor layer 621. Therefore, the first emission layer 622 and the first p-type semiconductor layer 623 may include a side surface formed as a curved surface along a circumference of the first n-type semiconductor layer 621.

The first p-type electrode 625 is disposed on the first p-type semiconductor layer 623.

Next, the first encapsulation layer 626 which encloses the first n-type semiconductor layer 621, the first emission layer 622, the first p-type semiconductor layer 623, the first n-type electrode 624, and the first p-type electrode 625 is disposed.

Referring to FIG. 7B, the second light emitting diode 630 includes a second n-type semiconductor layer 631, a second emission layer 632, a second p-type semiconductor layer 633, a second n-type electrode 634, a second p-type electrode 635, and a second encapsulation layer 636.

The second emission layer 632 and the second p-type semiconductor layer 633 are disposed on the second n-type semiconductor layer 631. The second n-type electrode 634 is disposed on one end portion of the second n-type semiconductor layer 631 and the second p-type electrode 635 is disposed on the other end portion of the second n-type semiconductor layer 631.

The planar shape of the second n-type semiconductor layer 631 of the second light emitting diode 630 may be an oval shape.

A planar shape of the second n-type electrode 634 may correspond to a partial shape of an oval. For example, a side surface of the second n-type electrode 634 adjacent to one end portion of the second n-type semiconductor layer 631 may be formed of a curved surface corresponding to the side surface of the second n-type semiconductor layer 631. In addition, a side surface of the second n-type electrode 634 adjacent to the other end portion of the second n-type semiconductor layer 631 may be formed of a plane which connects the side surface of the curved second n-type electrode 634.

At this time, the second emission layer 632 and the second p-type semiconductor layer 633 are spaced apart from the second n-type electrode 634 and may be disposed along the circumference of the second n-type electrode 634. For example, as illustrated in FIG. 7B, side surfaces of the second emission layer 632 and the second p-type semiconductor layer 633 which are opposite to the second n-type electrode 634 may be formed by a plane. In the meantime, on the other end portion of the second n-type semiconductor layer 631 in which the second n-type electrode 634 is not disposed, the second emission layer 632 and the second p-type semiconductor layer 633 may be disposed along a circumference of the second n-type semiconductor layer 631. Therefore, side surfaces of the second emission layer 632 and the second p-type semiconductor layer 633 may be formed as a convex curved surface along a circumference of the second n-type semiconductor layer 631.

The second p-type electrode 635 is disposed on the second p-type semiconductor layer 633.

Next, the second encapsulation layer 636 which encloses the second n-type semiconductor layer 631, the second emission layer 632, the second p-type semiconductor layer 633, the second n-type electrode 634, and the second p-type electrode 635 is disposed.

Referring to FIG. 7C, the third light emitting diode 640 includes a third n-type semiconductor layer 641, a third emission layer 642, a third p-type semiconductor layer 643, a third n-type electrode 644, a third p-type electrode 645, and a third encapsulation layer 646.

The third emission layer 642 and the third p-type semiconductor layer 643 are disposed on the third n-type semiconductor layer 641. The third n-type electrode 644 is disposed on one end portion of the third n-type semiconductor layer 641 and the third p-type electrode 645 is disposed on the other end portion of the third n-type semiconductor layer 641.

A planar shape of the third n-type semiconductor layer 641 of the third light emitting diode 640 may be formed by an oval shape which is different from the planar shape of the second n-type semiconductor layer 631 of the second light emitting diode 630.

A planar shape of the third n-type electrode 644 may correspond to a partial shape of an oval. For example, a side surface of the third n-type electrode 644 adjacent to one end portion of the third n-type semiconductor layer 641 may be formed of a curved surface corresponding to the side surface of the third n-type semiconductor layer 641. Further, a side surface of the third n-type electrode 644 adjacent to the other end portion of the third n-type semiconductor layer 641 may be formed of a plane which connects the side surface of the curved third n-type electrode 644.

The third emission layer 642 and the third p-type semiconductor layer 643 are spaced apart from the third n-type electrode 644 and may be disposed along the circumference of the third n-type electrode 644. For example, as illustrated in FIG. 7C, side surfaces of the third emission layer 642 and the third p-type semiconductor layer 643 which are opposite to the third n-type electrode 644 may be formed by a plane. In the meantime, on the other end portion of the third n-type semiconductor layer 641 in which the third n-type electrode 644 is not disposed, the third emission layer 642 and the third p-type semiconductor layer 643 may be disposed along a circumference of the third n-type semiconductor layer 641. Therefore, side surfaces of the third emission layer 642 and the third p-type semiconductor layer 643 may be formed as a convex curved surface along a circumference of the third n-type semiconductor layer 641.

The third p-type electrode 645 is disposed on the third p-type semiconductor layer 643.

Next, the third encapsulation layer 646 which encloses the third n-type semiconductor layer 641, the third emission layer 642, the third p-type semiconductor layer 643, the third n-type electrode 644, and the third p-type electrode 645 is disposed.

The second planarization layer 617 is disposed on the adhesive layer AD and the first connection electrode CE1 is disposed on the second planarization layer 617. The first connection electrode CE1 is disposed on one side of the plurality of light emitting diodes LED to be connected to n-type electrodes 624, 634, and 644 of the plurality of light emitting diodes LED. The first connection electrode CE1 may electrically connect the driving transistor DT, the n-type electrodes 624, 634, and 644 of the plurality of light emitting diodes LED and the n-type semiconductor layers 621, 631, and 641, respectively.

The third planarization layer 618 is disposed on the first connection electrode CE1 and the plurality of light emitting diodes LED.

In the display device 600 according to another exemplary embodiment of the present disclosure, the plurality of light emitting diodes LED may be disposed in various directions. Therefore, a color difference and a stain caused by the viewing angle change in the display panel PN may be minimized and a color uniformity may be improved.

In the meantime, the plurality of light emitting diodes dispersed in a fluid during the self-assembling process may collide with each other and may collide with the assembling substrate during the assembling process. Therefore, a part of the plurality of light emitting diodes may be broken due to the impact. For example, when n-type electrodes which are formed of a magnetic material are disposed on both sides of the light emitting diode, the n-type electrode disposed on one side of the light emitting diode may be broken at the boundary with the p-electrode.

In the meantime, when a voltage is applied to the plurality of assembly lines AL and the plurality of assembly electrodes AE, a part of the broken light emitting diode including the magnetic material may be assembled in the opening of the assembling substrate. Further, when the second light emitting diode and the third light emitting diode having a larger size than that of the first light emitting diode, among the plurality of light emitting diodes, are broken, a part of the broken second light emitting diode and third light emitting diode may be assembled in an area where the first light emitting diode is assembled. Therefore, when a part of the broken light emitting diode in which an n-type electrode and a p-type electrode remain is assembled in a position in which a light emitting diode emitting light with a different color is to be disposed, a dark spot and/or a bright spot failure may occur in the display panel.

Accordingly, in the display device 600 according to another exemplary embodiment of the present disclosure, n-type electrodes 624, 634, and 644 including a magnetic material of the plurality of light emitting diodes LED are disposed only in one side of the light emitting diode LED. Therefore, when the plurality of light emitting diodes LED is split in a boundary of the n-type electrodes 624, 634, and 644 and the p-type electrodes 625, 635, and 645, the p-type electrodes 625, 635, and 645 without a magnetism, between the n-type electrodes 624, 634, and 644 and the p-type electrodes 625, 635, and 645, may not be disposed in the opening. Further, when a part of the broken light emitting diode LED includes only the n-type electrodes 624, 634, and 644 having magnetism, the size of the broken light emitting diode LED is small so that a magnetic field enough to move to the assembling substrate may not be formed. Therefore, a part of the light emitting diode LED including only the n-type electrodes 624, 634, and 644 does not move to the assembling substrate, but may remain in the fluid. Accordingly, in the display device 600 according to another exemplary embodiment of the present disclosure, only a normal light emitting diode LED which is not broken is assembled on the assembling substrate and the broken light emitting diode remains in the fluid to improve an assembling rate.

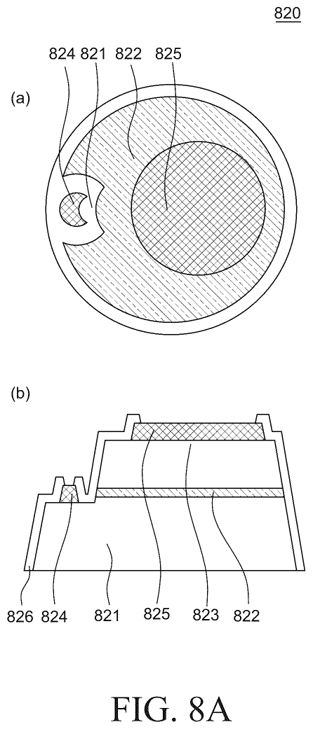

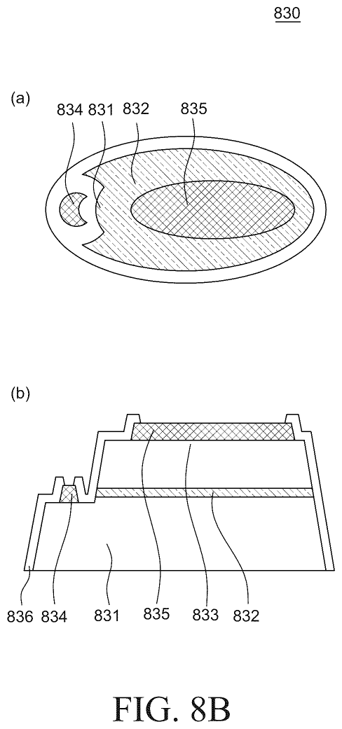

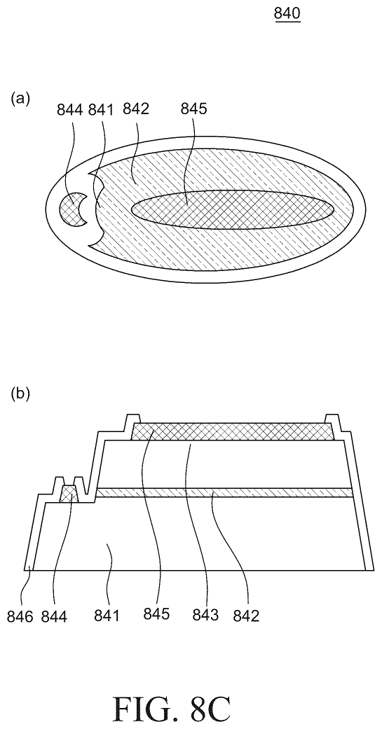

FIGS. 8A to 8C are views for explaining a plurality of light emitting diodes of a display device according to still another exemplary embodiment of the present disclosure. A plurality of light emitting diodes LED of a display device 800 of FIGS. 8A to 8C is only different from the light emitting diode LED of the display device 600 of FIGS. 6, 7A to 7C, but other configurations are substantially the same, so that a redundant description will be omitted.

Referring to FIG. 8A, a first light emitting diode 820 includes a first n-type semiconductor layer 821, a first emission layer 822, a first p-type semiconductor layer 823, a first n-type electrode 824, a first p-type electrode 825, and a first encapsulation layer 826.

The first n-type electrode 824 is disposed on one end portion of the first n-type semiconductor layer 821 and the first p-type electrode 825 is disposed on the other end portion of the first n-type semiconductor layer 821.

All the planar shapes of the first n-type semiconductor layer 821 of the first light emitting diode 820 may be a circular shape.

A planar shape of the first n-type electrode 824 may correspond to a partial shape of a circle. For example, a side surface of the first n-type electrode 824 adjacent to one end portion of the first n-type semiconductor layer 821 may be formed of a curved surface corresponding to the side surface of the first n-type semiconductor layer 821. At this time, a side surface of the first n-type electrode 824 which is opposite to a side surface of the first n-type electrode 824 which is formed as a curved surface may also be formed as a curved surface. At this time, two side surfaces of the first n-type electrode 824 which are opposite to each other are curved in the same direction and a planar shape of the first n-type electrode 824 may be a crescent shape.

The first emission layer 822 and the first p-type semiconductor layer 823 are disposed to be spaced apart from the first n-type electrode 824. At this time, as illustrated in FIG. 8A, when the first n-type electrode 824 is curved toward one side of the first n-type semiconductor layer 821, the first emission layer 822 and the first p-type semiconductor layer 823 which are opposite to the first n-type electrode 824 may protrude along the side surface of the first n-type electrode 824 in one direction. Therefore, the side surfaces of the first emission layer 822 and the first p-type semiconductor layer 823 which are opposite to the first n-type electrode 824 may protrude outwardly from the first light emitting diode 820.

In the meantime, on an end portion of the first n-type semiconductor layer 821 in which the first n-type electrode 824 is not disposed, the first emission layer 822 and the first p-type semiconductor layer 823 may be disposed along a circumference of the first n-type semiconductor layer 821. Therefore, the first emission layer 822 and the first p-type semiconductor layer 823 may include a side surface formed as a convex curved surface along a circumference of the first n-type semiconductor layer 821.

The first p-type electrode 825 is disposed on the first p-type semiconductor layer 823.

Next, the first encapsulation layer 826 which encloses the first n-type semiconductor layer 821, the first emission layer 822, the first p-type semiconductor layer 823, the first n-type electrode 824, and the first p-type electrode 825 is disposed.

Referring to FIG. 8B, the second light emitting diode 830 includes a second n-type semiconductor layer 831, a second emission layer 832, a second p-type semiconductor layer 833, a second n-type electrode 834, a second p-type electrode 835, and a second encapsulation layer 836.

The second n-type electrode 834 is disposed on one end portion of the second n-type semiconductor layer 831 and the second p-type electrode 835 is disposed on the other end portion of the second n-type semiconductor layer 831.

The planar shape of the second n-type semiconductor layer 831 of the second light emitting diode 830 may be formed as an oval shape.

A planar shape of the second n-type electrode 834 may correspond to a partial shape of an oval. For example, a side surface of the second n-type electrode 834 adjacent to one end portion of the second n-type semiconductor layer 831 may be formed of a curved surface corresponding to the side surface of the second n-type semiconductor layer 831. At this time, a side surface of the second n-type electrode 834 which is opposite to a side surface of the second n-type electrode 834 which is a curved surface may also be formed as a curved surface. At this time, two side surfaces of the second n-type electrode 834 which are opposite to each other are curved in the same direction and a planar shape of the second n-type electrode 834 may be a crescent shape.

The second emission layer 832 and the second p-type semiconductor layer 833 are disposed to be spaced apart from the second n-type electrode 834. At this time, as illustrated in FIG. 8B, when the second n-type electrode 834 is curved toward one side of the second n-type semiconductor layer 831, the second emission layer 832 and the second p-type semiconductor layer 833 which are opposite to the second n-type electrode 834 may protrude along the side surface of the second n-type electrode 834 in one direction. Therefore, the side surfaces of the second emission layer 832 and the second p-type semiconductor layer 833 which are opposite to the second n-type electrode 834 may protrude outwardly from the second light emitting diode 830.

In the meantime, on an end portion of the second n-type semiconductor layer 831 in which the second n-type electrode 834 is not disposed, the second emission layer 832 and the second p-type semiconductor layer 833 may be disposed along a circumference of the second n-type semiconductor layer 831. Therefore, the second emission layer 832 and the second p-type semiconductor layer 833 may include a side surface formed as a convex curved surface along a circumference of the second n-type semiconductor layer 831.

The second p-type electrode 835 is disposed on the second p-type semiconductor layer 833.

Next, the second encapsulation layer 836 which encloses the second n-type semiconductor layer 831, the second emission layer 832, the second p-type semiconductor layer 833, the second n-type electrode 834, and the second p-type electrode 835 is disposed.

Referring to FIG. 8C, the third light emitting diode 840 includes a third n-type semiconductor layer 841, a third emission layer 842, a second p-type semiconductor layer 843, a third n-type electrode 844, a third p-type electrode 845, and a third encapsulation layer 846.

A planar shape of the third n-type semiconductor layer 841 of the third light emitting diode 840 may be formed by an oval shape which is different from the planar shape of the second n-type semiconductor layer 830 of the second light emitting diode 831.

The third n-type electrode 844 is disposed on one end portion of the third n-type semiconductor layer 841 and the third p-type electrode 845 is disposed on the other end portion of the third n-type semiconductor layer 841.

The planar shape of the third n-type semiconductor layer 841 of the third light emitting diode 840 may be formed as an oval shape.

A planar shape of the third n-type electrode 844 may correspond to a partial shape of an oval. For example, a side surface of the third n-type electrode 844 adjacent to one end portion of the third n-type semiconductor layer 841 may be formed of a curved surface corresponding to the side surface of the third n-type semiconductor layer 841. At this time, a side surface of the third n-type electrode 844 which is opposite to a side surface of the third n-type electrode 844 which is a curved surface may also be formed as a curved surface. At this time, two side surfaces of the third n-type electrode 844 which are opposite to each other are curved in the same direction and a planar shape of the third n-type electrode 844 may be a crescent shape.

The third emission layer 842 and the third p-type semiconductor layer 843 are disposed to be spaced apart from the third n-type electrode 844. At this time, as illustrated in FIG. 8C, when the third n-type electrode 844 is curved toward one side of the third n-type semiconductor layer 841, the third emission layer 842 and the third p-type semiconductor layer 843 which are opposite to the third n-type electrode 844 may protrude along the side surface of the third n-type electrode 844 in one direction. Therefore, the side surfaces of the third emission layer 842 and the third p-type semiconductor layer 843 which are opposite to the third n-type electrode 844 may protrude outwardly from the third light emitting diode 840.

In the meantime, on an end portion of the third n-type semiconductor layer 841 in which the third n-type electrode 844 is not disposed, the third emission layer 842 and the third p-type semiconductor layer 843 may be disposed along a circumference of the third n-type semiconductor layer 841. Therefore, the third emission layer 842 and the third p-type semiconductor layer 843 may include a side surface formed as a convex curved surface along a circumference of the third n-type semiconductor layer 841.

The third p-type electrode 845 is disposed on the third p-type semiconductor layer 843.

Next, the third encapsulation layer 846 which encloses the third n-type semiconductor layer 841, the third emission layer 842, the third p-type semiconductor layer 843, the third n-type electrode 844, and the third p-type electrode 845 is disposed.

In the display device 800 according to still another exemplary embodiment of the present disclosure, the plurality of light emitting diodes LED is disposed in various directions. Therefore, a color difference and a stain caused by the viewing angle change in the display panel PN may be minimized and a color uniformity may be improved.

In the display device 800 according to still another exemplary embodiment of the present disclosure, n-type electrodes 824, 834, and 844 including a magnetic material of the plurality of light emitting diodes LED are disposed only in one side of the light emitting diode LED. Accordingly, only a normal light emitting diode LED which is not broken is assembled on the assembling substrate and the broken light emitting diode remains in the fluid so that the assembling rate may be improved.

In the display device 800 according to still another exemplary embodiment of the present disclosure, n-type electrodes 824, 834, and 844 of the plurality of light emitting diodes LED are disposed to be curved toward one side of the light emitting diode LED. Therefore, the emission layers 822, 832, and 842 and the p-type semiconductor layers 823, 833, and 843 which are opposite to the n-type electrodes 824, 834, and 844 are formed to protrude outwardly from the light emitting diode LED to expand the area of the emission layers 822, 832, and 842. Therefore, a luminous efficiency of the light emitting diode LED may be improved.

Hereinafter, after describing an assembling substrate 1000 and a donor 2000 according to an exemplary embodiment of the present disclosure, first, with reference to FIGS. 9 to 11B, a method of manufacturing a display device according to various exemplary embodiments of the present disclosure will be described.

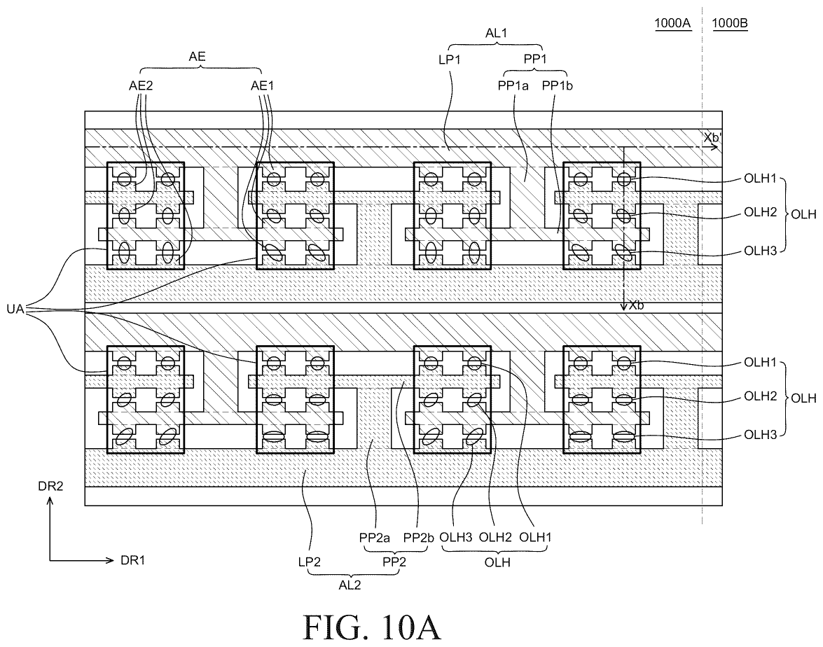

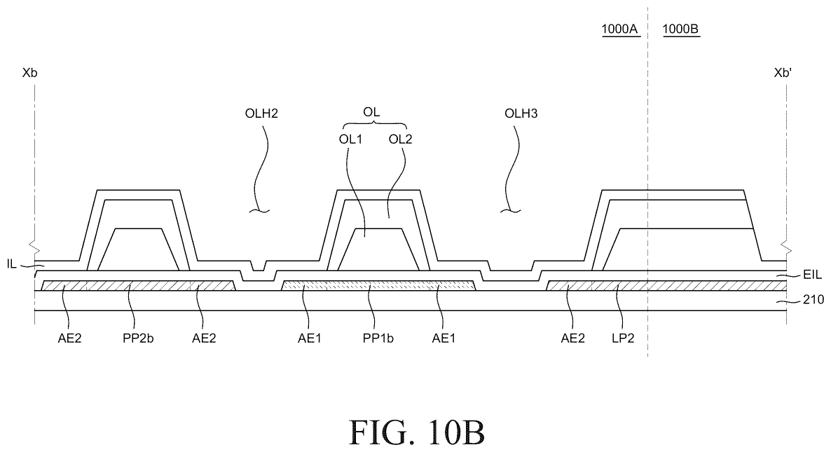

FIG. 9 is a plan view of an assembling substrate according to an exemplary embodiment of the present disclosure. FIG. 10A is an enlarged plan view of an assembly area of an assembling substrate of a display device according to an exemplary embodiment of the present disclosure. FIG. 10B is a cross-sectional view of a display device taken along Xb-Xb′ of FIG. 10A.

Referring to FIG. 9, the assembling substrate 1000 includes an assembly area 1000A and an outer peripheral area 1000B. The assembly area 1000A is an area in which the plurality of light emitting diodes LED is self-assembled and a plurality of assembly lines AL and a plurality of assembly electrodes AE for self-assembling the light emitting diode LED are disposed. The outer peripheral area 1000B is a remaining area excluding the assembly area 1000A and a plurality of assembly pads, a plurality of alignment keys, and the like may be disposed therein.

Referring to FIGS. 9 to 10C, the assembling substrate 1000 includes an assembly substrate 1010, a plurality of assembly lines AL, a plurality of assembly electrodes AE, a plurality of assembly pads, an electrode insulating layer EIL, an organic layer OL, and an assembly insulating layer IL.

First, referring to FIGS. 10A and 10B, in the assembly area 1000A, the plurality of assembly lines AL and the plurality of assembly electrodes AE are disposed on the assembly substrate 1010.

The plurality of assembly lines AL includes a plurality of first assembly lines AL1 and a plurality of second assembly lines AL2. The plurality of first assembly lines AL1 and the plurality of second assembly lines AL2 may be disposed to be spaced apart from each other with a predetermined interval. The plurality of first assembly lines AL1 and the plurality of second assembly lines AL2 may alternately be disposed. The plurality of first assembly lines AL1 and the plurality of second assembly lines AL2 are applied with different voltages so that an electric field may be formed between the plurality of first assembly lines AL1 and the plurality of second assembly lines AL2. The plurality of light emitting diodes LED may be self-assembled between the plurality of first assembly lines AL1 and the plurality of second assembly lines AL2 using the electric field formed between the plurality of first assembly lines AL1 and the plurality of second assembly lines AL2.

Each of the plurality of first assembly lines AL1 includes a first line parts LP1 and a plurality of first protrusion parts PP1. The first line part LP1 is a part which straightly extends from the assembly area 1000A along a first direction DR1. The first line part LP1 extends from the assembly area 1000A to the outer peripheral area 1000B and may be electrically connected to the plurality of assembly pads of the outer peripheral area 1000B.

The plurality of first protrusion parts PP1 is connected to one first line part LP1. The plurality of first protrusion parts PP1 may extend from one side surface of the first line part LP1 toward a second assembly line AL2 adjacent thereto. The plurality of first protrusion parts PP1 may be disposed to self-assemble each of the plurality of first light emitting diodes 120, the plurality of second light emitting diodes 130, and the plurality of third light emitting diodes 140 between one first assembly line AL1 and one second assembly line AL2 which are adjacent to each other. The plurality of first protrusion parts PP1 is disposed to be alternate with a plurality of second protrusion parts PP2 of the second assembly line AL2 to be described below and may form a plurality of electric fields to self-assemble the light emitting diode LED so as to correspond to each of the plurality of first sub pixels SP1, the plurality of second sub pixels SP2, and the plurality of third sub pixels SP3. Accordingly, the plurality of first protrusion parts PP1 is disposed between an area between the first assembly line AL1 and the second assembly line AL2 to self-assemble the first light emitting diode 120, the second light emitting diode 130, and the third light emitting diode 140 with an interval between the plurality of sub pixels SP.

If each of the plurality of first light emitting diodes 120, the plurality of second light emitting diodes 130, and the plurality of third light emitting diodes 140 is self-assembled using different assembly lines AL, all an assembly line AL for self-assembling the first light emitting diode 120, an assembly line AL for self-assembling the second light emitting diode 130, and an assembly line AL for self-assembling the third light emitting diode 140 are necessary. In this case, the number of the plurality of assembly lines AL is increased so that it may be difficult to secure a design area. Further, during a process of forming the assembly line AL so as to correspond to the interval between the sub pixels SP, a width of the assembly line AL is reduced to increase the resistance, which may lead to the deterioration of an assembly rate.

Accordingly, in order to self-assemble all the first light emitting diodes 120, the second light emitting diodes 130, and the third light emitting diodes 140 between one first assembly line AL1 and one second assembly line AL2 which are adjacent to each other, the plurality of first protrusion parts PP1 may be connected to one first line part LP1.

Each of the plurality of first protrusion parts PP1 includes a first part PP1a and a second part PP1b. The first part PP1a is a part extending from the first line part LP1 toward a second direction DR2. The first part PP1a may be a connection member for transmitting a voltage to the second part PP1b. One end of the first part PP1a may be connected to the first line part LP1 and the other end may be connected to the second part PP1b.

The second part PP1b is connected to the other end of the first part PP1a and extends to the first direction DR1. The second part PP1b may be alternately disposed with the second protrusion part PP2 of the second assembly line AL2 while extending to the first direction DR1. The second part PP1b may be disposed in the area between a fourth part PP2b of the second protrusion part PP2 of the second assembly line AL2 and the second line part LP2. The second part PP1b is disposed to be adjacent to the fourth part PP2b of the second protrusion part PP2 and the second line part LP2 to form an electric field to self-assemble the plurality of first light emitting diodes 120, the plurality of second light emitting diodes 130, and the plurality of third light emitting diodes 140.

Each of the plurality of second assembly lines AL2 includes a second line part LP2 and a plurality of second protrusion parts PP2. The second line part LP2 is a part which straightly extends from the assembly area 1000A along a first direction DR1. In the second direction DR2, the second line part LP2 may be disposed alternately with the first line part LP1. The second line part LP2 extends from the assembly area 1000A to the outer peripheral area 1000B and may be electrically connected to the plurality of assembly pads of the outer peripheral area 1000B.

A plurality of second protrusion parts PP2 is connected to the second line part LP2. The plurality of second protrusion parts PP2 may extend from the other side surface of the second line part LP2 to the second direction DR2. Each of the plurality of second protrusion parts PP2 includes a third part PP2a and a fourth part PP2b. The third part PP2a is a part extending from the second line part LP2 to the second direction DR2. The third part PP2a may be a connection member for transmitting a voltage to the fourth part PP2b. One end of the third part PP2a may be connected to the second line part LP2 and the other end may be connected to the fourth part PP2b. The third part PP2a may be disposed alternately with the first part PP1a of the first assembly line AL1 adjacent thereto. Accordingly, the third part PP2a and the first part are alternately disposed so that the fourth part PP2b connected to the third part PP2a may be disposed alternately with the second part PP1b connected to the first part PP1a.

The fourth part PP2b is connected to the other end of the third part PP2a and extends to the first direction DR1. The fourth part PP2b extends to the first direction DR1 and may be alternately disposed with the second part PP1b of the first protrusion part PP1 of the first assembly line AL1. The fourth part PP2b may be disposed in the area between the second part PP1b of the first protrusion part PP1 of the first assembly line AL1 and the first line part LP1. In the second direction DR2, the fourth part PP2b of the second assembly line AL2 and the second part PP1b of the first assembly line AL1 may face each other. Accordingly, the fourth part PP2b of the second assembly line AL2 may form an electric field to self-assemble the plurality of first light emitting diodes 120, the plurality of second light emitting diodes 130, and the plurality of third light emitting diodes 140 together with the first line part LP1 and the second part PP1b of the first assembly line AL1 adjacent thereto.

The plurality of assembly electrodes AE includes a plurality of first assembly electrodes AE1 and a plurality of second assembly electrodes AE2. The plurality of first assembly electrodes AE1 may be connected to the plurality of first assembly lines AL1 and the plurality of second assembly electrodes AE2 may be connected to the plurality of second assembly lines AL2. One pair of first assembly electrode AE1 and second assembly electrode AE2 is disposed to be adjacent to each other to form an electric field to self-assemble the light emitting diode LED. Each of one pair of first assembly electrode AE1 and second assembly electrode AE2 may be disposed to correspond to a correct position in which the light emitting diode LED is transferred in the plurality of sub pixels SP.

Some of the plurality of first assembly electrodes AE1 may be disposed to protrude from one side surface of the first line part LP1 toward the second direction DR2. The other portions of the plurality of first assembly electrodes AE1 may be disposed to protrude from both side surfaces of the second part PP1b of the first protrusion part PP1 toward the second direction DR2. For example, four first assembly electrodes AE1 may be connected to each of both side surfaces of one second part PP1b.

Some of the plurality of second assembly electrodes AE2 may be disposed to protrude from the other side surface of the second line part LP2 toward the second direction DR2. Some second assembly electrodes AE2 connected to the second line part LP2 may face the first assembly electrode AE1 which protrudes from the second part PP1b of the first assembly line AL1 adjacent thereto. Some of the plurality of second assembly electrodes AE1 may be disposed to protrude from both side surfaces of the fourth part PP2b of the second protrusion part PP2 toward the second direction DR2. Among these, the second assembly electrode AE2 protruding from one side surface of the fourth part PP2b may face the first assembly electrode AE1 which protrudes from the other side surface of the second part PP1b of the first assembly line AL1 adjacent thereto. The second assembly electrode AE2 protruding from the other side surface of the fourth part PP2b may face the first assembly electrode AE1 which protrudes from the first line part LP1 of the first assembly line AL1 adjacent thereto.

Any one of the first light emitting diode 120, the second light emitting diode 130, and the third light emitting diode 140 may be self-assembled between the first assembly electrode AE1 and the second assembly electrode AE2 which face each other, with an interval and an arrangement corresponding to each of the plurality of sub pixels SP. For example, the first light emitting diode 120 may be self-assembled between the first assembly electrode AE1 of the first line part LP1 and the second assembly electrode AE2 of the fourth part PP2b which face each other. The second light emitting diode 130 may be self-assembled between the first assembly electrode AE1 of the second part PP1b and the second assembly electrode AE2 of the fourth part PP2b which face each other. The third light emitting diode 140 may be self-assembled between the first assembly electrode AE1 of the second part PP1b and the second assembly electrode AE2 of the second line part LP2 which face each other.

Accordingly, the plurality of first protrusion parts PP1 and the plurality of second protrusion parts PP2 are alternately disposed between one first assembly line AL1 and the second assembly line AL2 which are adjacent to each other. By doing this, the first light emitting diode 120 of the first sub pixel SP1, the second light emitting diode 130 of the second sub pixel SP2, and the third light emitting diode 140 of the third sub pixel SP3 may be self-assembled at one time.

In the meantime, referring to FIG. 10A, the plurality of first assembly electrodes AE1 and the plurality of second assembly electrodes AE2 are disposed in each of the plurality of unit areas UA and disposed in a position corresponding to a plurality of opening OLH. At this time, all shapes of the plurality of first assembly electrodes AE1 and the plurality of second assembly electrodes AE2 may be the same in the plurality of unit areas UA. For example, as illustrated in FIG. 10A, a planar shape of each of the first assembly electrodes AE1 and the plurality of second assembly electrodes AE2 disposed in one unit area UA may be a rectangle, but is not limited thereto.

Referring to FIG. 9 together, a plurality of assembly pads is disposed on the assembling substrate 1000 in the outer peripheral area 1000B. The plurality of assembly pads includes a plurality of first assembly pads APAD1 and a plurality of second assembly pads APAD2. The plurality of first assembly lines AL1 and the plurality of first assembly electrodes AE1 are connected to the plurality of first assembly pads APAD1 to be applied with a voltage. The plurality of second assembly lines AL2 and the plurality of second assembly electrodes AE2 are connected to the plurality of second assembly pads APAD2 to be applied with a voltage. Some first assembly lines AL1 among the plurality of first assembly lines AL1 may be connected to one first assembly pad APAD1 and some second assembly lines AL2 among the plurality of second assembly lines AL2 may be connected to one second assembly pad APAD2.

Next, the electrode insulating layer EIL is disposed on the plurality of assembly lines AL and the plurality of assembly electrodes AE. The electrode insulating layer EIL may be configured by a single layer or a double layer of silicon oxide SiOx or silicon nitride SiNx, but is not limited thereto.

The organic layer OL including a plurality of openings OLH is disposed. The organic layer OL includes a first organic layer OL1 and a second organic layer OL2. The first organic layer OL1 is disposed on the plurality of assembly lines AL and the second organic layer OL2 is disposed on the first organic layer OL1. A thickness of the organic layer OL which can be formed by one process is limited. If the thickness of the organic layer OL is equal to or lower than a predetermined level, the light emitting diode LED which is self-assembled in the opening OLH of the organic layer OL may not be properly seated in the opening OLH. In contrast, when the thickness of the organic layer OL is excessively thick, it may be difficult to attach the light emitting diode LED which is self-assembled in the opening OLH of the organic layer OL to the donor 2000. Therefore, the thickness of the organic layer OL may be adjusted by forming a plurality of organic layers OL. The organic layer OL may at least have a thickness smaller than a height of the light emitting diode LED. Even though in FIG. 10B, it is illustrated that the organic layer OL includes a first organic layer OL1 and a second organic layer OL2, the organic layer OL may be formed as a single layer or further include an additional organic layer OL, in addition to the first organic layer OL1 and the second organic layer OL2. However, it is not limited thereto.

The organic layer OL includes a plurality of openings OLH. Each of the plurality of openings OLH which is formed by opening a part of the organic layer OL is an area in which the plurality of light emitting diodes LED is self-assembled. The plurality of openings OLH may be disposed so as to overlap an area between one pair of the first assembly electrode AE1 and the second assembly electrode AE2. Each of the plurality of openings OLH may be formed in a position of the display device 100 corresponding to each of the plurality of sub pixels SP, later. The plurality of openings OLH may be disposed to correspond to the plurality of sub pixels SP one to one and the light emitting diode LED which is self-assembled in the plurality of openings OLH may be transferred onto the plurality of sub pixels SP as it is.

The plurality of openings OLH includes a plurality of first openings OLH1, a plurality of second openings OLH2, and a plurality of third openings OLH3. Each of the plurality of first openings OLH1, the plurality of second openings OLH2, and the plurality of third openings OLH3 may be disposed so as to correspond to the plurality of first sub pixels SP1, the plurality of second sub pixels SP2, and the plurality of third sub pixels SP3.

In the meantime, the plurality of openings OLH may form the plurality of unit areas UA. The plurality of unit areas UA is an area corresponding to one pixel PX and each of the plurality of unit areas UA may be formed in a position corresponding to each of the plurality of pixels PX of the display device 100. Each of the plurality of unit areas UA may be disposed to correspond to each of the pixels PX one by one and the light emitting diode LED self-assembled in each of the plurality of unit areas UA may be transferred to each of the plurality of pixels PX.

In FIG. 10A, it is illustrated that one unit area UA is formed by one pair of first openings OLH1, one pair of second openings OLH2, and one pair of third openings OLH3, but it is not limited thereto.

The plurality of first openings OHL1 may have a shape corresponding to a planar shape of the first light emitting diode 120. The plurality of second openings OHL2 may have a shape corresponding to a planar shape of the second light emitting diode 130. The plurality of third openings OHL3 may have a shape corresponding to a planar shape of the third light emitting diode 140. For example, the plurality of first openings OHL1 may be a plurality of circular openings, the plurality of second openings OHL2 may be a plurality of first oval openings, and the plurality of third openings OHL3 may be a plurality of second oval openings. Therefore, the first opening OLH1 is formed to have a circular shape so that only the first light emitting diode 120 may be self-assembled in the first opening OLH1 and the second opening OLH2 is formed to have an oval shape so that only the second light emitting diode 130 may be self-assembled in the second opening OLH2. The third opening OLH3 is formed to have an oval shape having a long axis longer than that of the second opening OLH2 so that only the third light emitting diode 140 may be self-assembled in the third opening OLH3. Accordingly, the first opening OLH1, the second opening OLH2, and the third opening OLH3 are formed to have shapes corresponding to the first light emitting diode 120, the second light emitting diode 130, and the third light emitting diode 140. Therefore, only a light emitting diode having a specific shape may be self-assembled in each opening OLH.

In the meantime, the plurality of openings OLH may be disposed in various directions. For example, in one unit area UA, each of the second opening OLH2 and the third opening OLH3 may be disposed along a direction different from that of the second opening OLH2 and the third opening OLH3 disposed in an adjacent unit area UA. For example, in one unit area UA, long axes of the second opening OLH2 and the third opening OLH3 may be disposed along the first direction DR1 and in another unit area UA, the long axes of the second opening OLH2 and the third opening OLH3 may be disposed along the second direction DR2. Further, in still another unit area UA, the long axes of the second opening OLH2 and the third opening OLH3 may be disposed along a direction between the first direction DR1 and the second direction DR2. Therefore, in at least one unit area UA, among the plurality of unit areas UA, the long axis directions of the second opening OLH2 and the third opening OLH3 may be different from the long axis directions of the second opening OLH2 and the third opening OLH3 in the adjacent unit area UA. In the meantime, the shape of the plurality of openings OLH illustrated in FIG. 10A is illustrated for the convenience of description so that the present disclosure is not limited thereto. Therefore, the long axes of the plurality of openings OLH may be disposed in various directions and also in one unit area UA, the long axes of the second opening OLH2 and the third opening OLH3 may be disposed in a random direction.

In the meantime, in the plurality of unit areas UA, all the plurality of first assembly electrodes AE1 and the plurality of second assembly electrodes AE2 are disposed in the same direction with the same shape. Therefore, an area where the second opening OLH2 and the third opening OLH3 overlap the plurality of first assembly electrodes AE1 and the plurality of second assembly electrodes AE2 in one unit area UA may be different from an area where the second opening OLH2 and the third opening OLH3 overlap the plurality of first assembly electrodes AE1 and the plurality of second assembly electrodes AE2 in the adjacent unit area UA.

The assembly insulating layer IL is disposed on the organic layer OL and the electrode insulating layer EIL. The assembly insulating layer IL may protect the plurality of assembly lines AL, the plurality of assembly electrodes AE, and the organic layer OL from the fluid WT to suppress the defect such as corrosion of the plurality of assembly lines AL.

In the meantime, referring to FIGS. 10A and 10B, the assembly insulating layer IL may expose a side surface of the organic layer OL in the outer peripheral area 1000B. In the outer peripheral area 1000B, the first line part LP1 and the second line part LP2 extending from the assembly area 1000A are electrically connected to the plurality of assembly pads. Therefore, in the outer peripheral area 1000B, the assembly insulating layer IL is removed together with the organic layer OL and may expose the side surface of the organic layer OL, but it is not limited thereto.

Referring to FIG. 9 together, the outer peripheral area 1000B includes one or more first alignment areas 1000Ba. The first alignment area 1000Ba is an area in which a plurality of first alignment patterns is disposed and a plurality of alignment keys is self-assembled. For example, each of the plurality of first alignment areas 1000Ba may be formed to be adjacent to each of four corners of the assembly area 1000A.

In the first alignment area 1000Ba, the plurality of first alignment patterns is disposed on the assembling substrate 1000. The plurality of first alignment patterns is marks for aligning the donor 2000 to be described below and the assembling substrate 1000. The assembling substrate 1000 and the donor 2000 may be aligned by aligning a plurality of first alignment patterns of the assembling substrate 1000 and a plurality of second alignment patterns of the donor 2000. For example, the plurality of first alignment patterns may be formed to have a donut shape.

In the first alignment area 1000Ba, an assembly line AL and an assembly electrode AE may further be disposed on the assembling substrate 1000. The assembly line AL disposed in the first alignment area 1000Ba may apply a voltage to the assembly electrode AE to form an electric field for self-assembling the alignment key in the assembly electrode AE.

The alignment key may be self-assembled in an area between the assembly electrodes AE of the first alignment area 1000Ba. The alignment key may be transferred to the donor 2000 together with the plurality of light emitting diodes LED and the alignment key transferred to the donor 2000 may be used to align the donor 2000 and the display panel PN. That is, the alignment key is a mark for aligning the donor 2000 and the display panel PN. The alignment key may be formed of the same material as at least a part of materials which form the light emitting diode LED. For example, the first light emitting diode 120 may be used as the alignment key. In this case, the first opening OLH1 of the organic layer OL may be formed on the assembly electrode AE to self-assemble only the first light emitting diode 120 which serves as the alignment key.

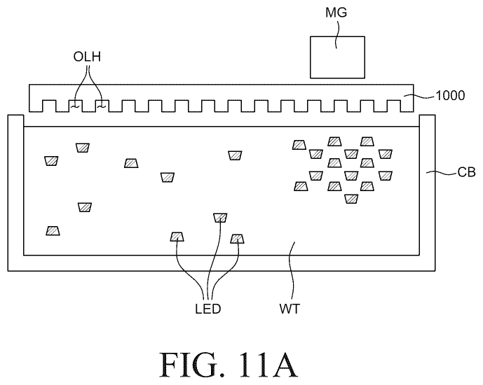

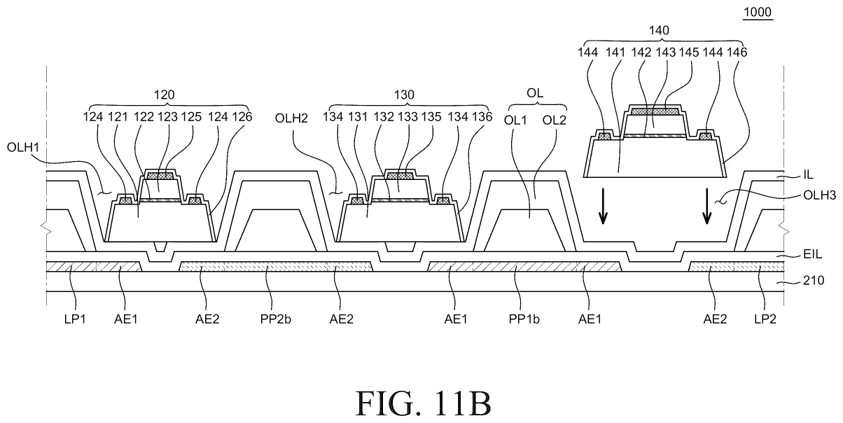

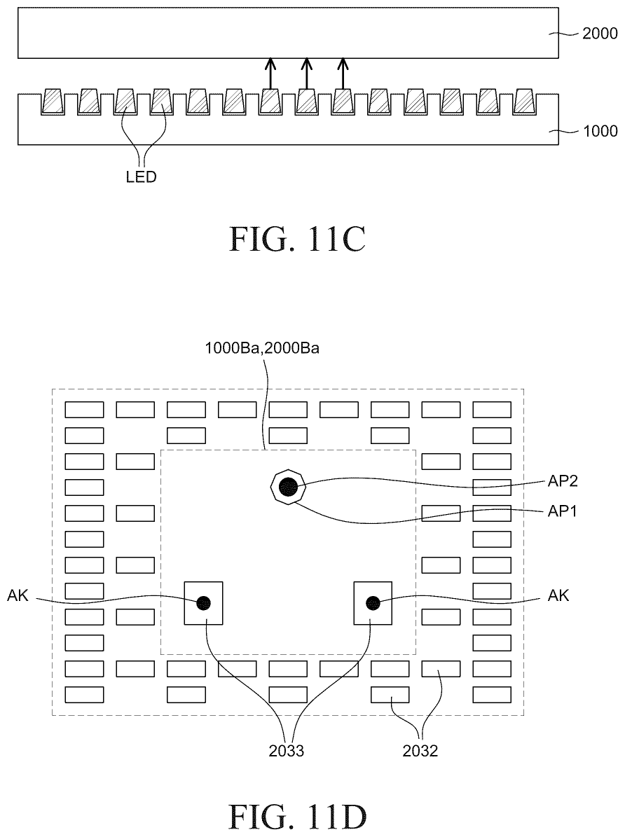

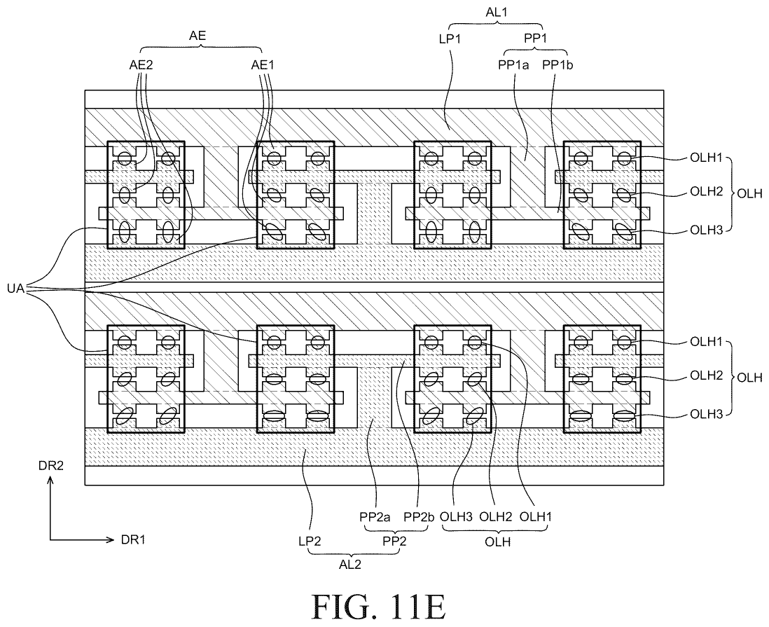

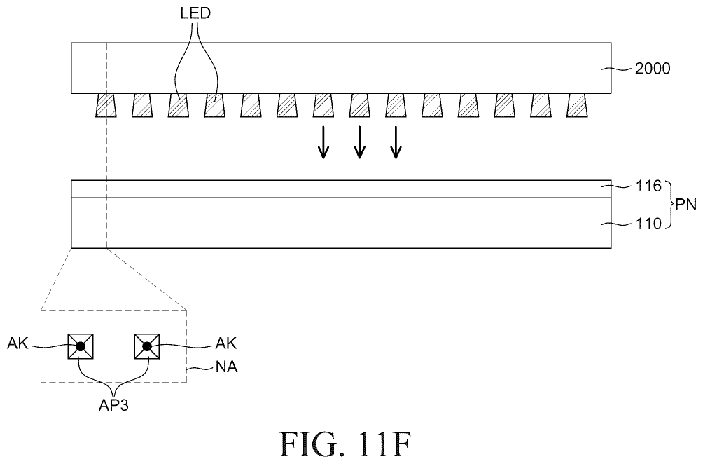

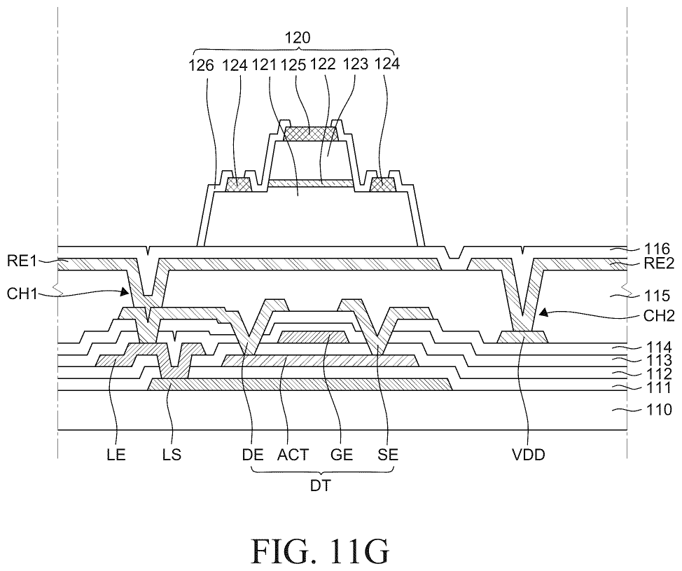

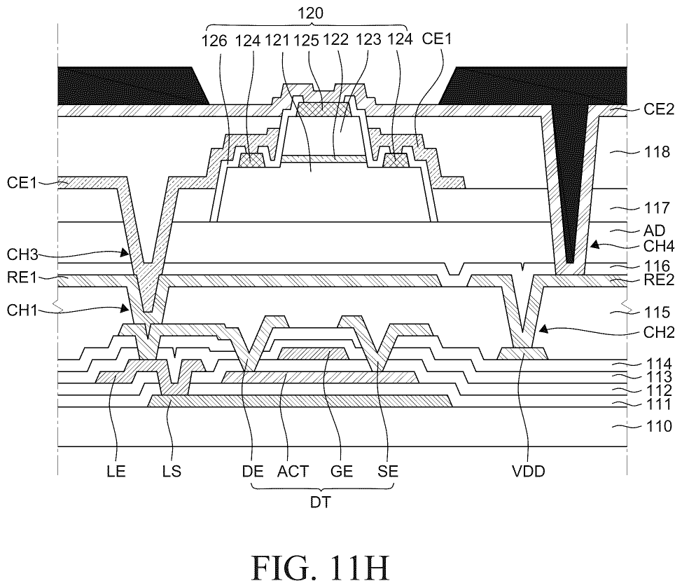

Hereinafter, a method of manufacturing a display device 100 according to an exemplary embodiment of the present disclosure will be described with reference to FIGS. 11A to 11H.

FIGS. 11A to 11H are process diagrams for explaining a method of manufacturing a display device according to an exemplary embodiment of the present disclosure. FIGS. 11A and 11B are views for explaining a process of self-assembling a light emitting diode LED on an assembling substrate 1000. FIG. 11C is a view for explaining a process of transferring the light emitting diode LED on the assembling substrate 1000 onto the donor 2000. FIG. 11D is a plan view of a first alignment area 1000Ba and a second alignment area 2000Bb when the assembling substrate 1000 and the donor 2000 are bonded. FIG. 11E is a plan view of an assembly area 1000A and a transferring area 2000A when the assembling substrate 1000 and the donor 2000 are bonded. FIGS. 11F and 11G are views for explaining a process of transferring the light emitting diode LED on the donor 2000 to the display panel PN. FIG. 11H is a cross-sectional view of a display panel PN for explaining a process of forming a first connection electrode CE1 and a second connection electrode CE2.

Referring to FIG. 11A, the plurality of light emitting diodes LED is self-assembled on the assembling substrate 1000.

First, the light emitting diode LED which is grown on the wafer is input into a chamber CB filled with a fluid WT. The fluid WT may include water, etc. and a top of the chamber CB filled with fluid WT may be open.

Next, the assembling substrate 1000 may be located on the chamber CB filled with the light emitting diode LED. The assembling substrate 1000 may be disposed such that the organic layer OL on which the plurality of openings OLH of the assembling substrate 1000 is formed and the chamber CB face each other.

Next, a magnet MG may be located on the assembling substrate 1000. The light emitting diodes LED sinking on the bottom of the chamber CB or floating may move toward the assembling substrate 1000 by a magnetic force of the magnet MG.

At this time, the light emitting diode LED may include magnetic materials to move by the magnetic field. For example, any one of n-type electrodes 124, 134, and 144 or p-type electrodes 125, 135, and 145 of the light emitting diode LED includes a ferromagnetic material such as iron (Fe), cobalt (Co), or nickel (Ni) to align a direction of the light emitting diode LED directed to the magnet MG.

Next, referring to FIG. 11B, the light emitting diode LED which is moved to the assembling substrate 1000 by the magnet MG may be self-assembled on the assembling substrate 1000 by an electric field formed between a plurality of assembly electrodes AE.

Specifically, a voltage is applied to the plurality of assembly lines AL and the plurality of assembly electrodes AE to self-assemble the plurality of light emitting diodes LED in the opening OLH of the organic layer OL. For example, different AC voltages are applied to the plurality of first assembly lines AL1 and the plurality of first assembly electrodes AE1, and the plurality of second assembly lines AL2 and the plurality of second assembly electrodes AE2 to form an electric field. The light emitting diode LED is dielectrically polarized by the electric field to have a polarity. The dielectrically polarized light emitting diode LED may move or may be fixed to a specific direction by dielectrophoresis (DEP), that is, an electric field. Accordingly, the plurality of light emitting diodes LED may be temporarily self-assembled in the opening OLH of the assembling substrate 1000 using dielectrophoresis.

At this time, the second light emitting diode 130 and the third light emitting diode 140 having an oval shape may be aligned such that one pair of n-type electrodes is directed to adjacent assembly electrodes AE. For example, the second light emitting diode 130 is aligned such that one of one pair of second n-type electrodes 134 is directed to the first assembly electrode AE1 and the other one is directed to the second assembly electrode AE2. By doing this, the second light emitting diode may be self-assembled in the second opening OLH2.

In the meantime, the second light emitting diode 130 and the third light emitting diode 140 having an oval shape may be aligned along the long axis directions of the second opening OLH2 and the third opening OLH3, respectively. At this time, the second light emitting diode 130 and the third light emitting diode 140 may be self-assembled on the assembling substrate 1000 in various directions along the long axis directions of the second opening OLH2 and the third opening OLH3, respectively. For example, when the long axis direction of each of the second opening OLH2 and the third opening OLH3 in one unit area UA is different from the long axis direction of each of the second opening OLH2 and the third opening OLH3 disposed in an adjacent unit area UA, the long axis of each of the second light emitting diode 130 and the third light emitting diode 140 in one unit area UA may be self-assembled in a different direction from the long axis of each of the second light emitting diode 130 and the third light emitting diode 140 disposed in the adjacent unit area UA.

After completing the self-assembling, the fluid WT may be evaporated from the assembling substrate 1000. At this time, the electric field is formed between the assembly electrodes AE before completely evaporating the fluid WT to fix the light emitting diode LED into the opening OLH. When the drying of the assembling substrate 1000 is completed, the electric field may be removed. At this time, even after removing the electric field, the light emitting diode LED may be temporarily fixed to the assembling substrate 1000 by means of Van der Waals force.

Next, referring to FIGS. 11C to 11E, the plurality of light emitting diodes LED and the plurality of alignment keys AK of the assembling substrate 1000 are transferred onto the donor 2000.

First, referring to FIGS. 11C and 11D, the assembling substrate 1000 and the donor 2000 are aligned such that the plurality of light emitting diodes LED and the donor 2000 face each other. At this time, the assembling substrate 1000 and the donor 2000 may be aligned by overlapping the first alignment area 1000Ba of the assembling substrate 1000 and the second alignment area 2000Bb of the donor 2000. For example, the assembling substrate 1000 and the donor 2000 may be aligned such that the first alignment pattern AP1 of the assembling substrate 1000 and the second alignment pattern AP2 of the donor 2000 overlap each other. The assembling substrate 1000 and the donor 2000 may be aligned such that the circular second alignment pattern AP2 is disposed in an empty space in the donut-shaped first alignment pattern AP1. In the non-transferring area in the donor 2000, a plurality of dummy bumps 2032 and a plurality of alignment bumps 2033 are included in the transferring area. The plurality of dummy bumps 2032 may improve the bonding strength of the assembling substrate 1000 and the donor 2000 during the transferring process and may minimize the deformation of the plurality of chip bumps disposed in the transferring area due to the shock which is applied to the donor 2000. Further, the plurality of dummy bumps 2032 is in contact with the organic layer OL of the assembling substrate 1000 to maintain the bonded state of the assembling substrate 1000 and the donor 2000.

In this case, the alignment key AK of the assembling substrate 1000 may be aligned to overlap the alignment bump 2033 disposed in the non-transferring area in the donor 2000.

Referring to FIG. 11E, when the first alignment pattern AP1 and the second alignment pattern AP2 are aligned, the plurality of chip bumps 2031 may be aligned so as to correspond to the plurality of light emitting diodes LED, respectively. Each of the plurality of chip bumps 2031 may be disposed above one pair of first light emitting diodes 120, one pair of second light emitting diodes 130, and one pair of third light emitting diodes 140.

Accordingly, after aligning the assembling substrate 1000 and the donor 2000, the assembling substrate 1000 and the donor 2000 may be bonded so that the upper portion of the light emitting diode LED may be in contact with the donor 2000. At this time, the donor 2000 is formed of a material having adhesiveness so that upper portions of the plurality of light emitting diodes LED are bonded to the donor 2000 to move from the assembling substrate 1000 to the donor 2000. At this time, the plurality of light emitting diodes LED aligned in the random direction on the assembling substrate 1000 may move to the donor 2000 while maintaining the alignment direction.

The plurality of alignment keys AK may also be transferred to the alignment bump 2033 of the donor 2000 together with the plurality of light emitting diodes LED which is transferred to the plurality of chip bumps 2031.

Next, referring to FIG. 11F, the plurality of light emitting diodes LED on the donor 2000 is transferred onto the adhesive layer AD of the display panel PN.

First, the display panel PN with the adhesive layer AD and the donor 2000 are aligned. After disposing the donor 2000 such that the plurality of light emitting diodes LED of the donor 2000 faces the adhesive layer AD of the display panel PN with each other, the display panel PN and the donor 2000 may be aligned. When the display panel PN and the donor 2000 are aligned, the alignment key AK which is temporarily attached onto the alignment bump 2033 of the donor 2000 is aligned with the third alignment pattern AP3 of the display panel PN to align the donor 2000 and the display panel PN. The third alignment pattern AP3 is a pattern disposed in the non-active area NA of the display panel PN and may be formed of the same material as any one of the plurality of wiring lines or the plurality of electrodes disposed in the display panel PN. For example, the third alignment pattern AP3 may be formed in a rectangular shape in which an X-shaped pattern is disposed therein. Therefore, the donor 2000 and the display panel PN may be aligned to dispose the alignment key AK in a center of the X-shaped portion of the third alignment pattern AP3.

Further, referring to FIGS. 11F and 11G together, the donor 2000 and the display device 100 are bonded to transfer the light emitting diode LED on the donor 2000 onto the adhesive layer AD. The plurality of light emitting diodes LED disposed on the donor 2000 is disposed so as to correspond to the plurality of sub pixels SP so that all the light emitting diodes LED on the donor 2000 may be transferred onto the display panel PN at one time without selectively transferring the light emitting diodes LED. The plurality of light emitting diodes LED which is transferred onto the display panel PN is attached onto the adhesive layer AD to be temporarily fixed.

At this time, the plurality of light emitting diodes LED aligned in the various directions on the donor 2000 may move to the display panel PN while maintaining the alignment direction.

The alignment key AK may be transferred together with the plurality of light emitting diodes LED. The alignment key AK may be transferred onto the third alignment pattern AP3 of the non-active area NA. However, the alignment key AK which is transferred to the display panel PN is not connected to a separate connection electrode CE so that it does not emit light.

Next, referring to FIG. 11H, after transferring the light emitting diode LED onto the adhesive layer AD of the display panel PN, the first connection electrode CE1 and the second connection electrode CE2 are formed to electrically connect the light emitting diode LED to the driving transistor DT and the power line VDD.

First, the second planarization layer 117 which covers the plurality of light emitting diodes LED is formed. At this time, the thickness of the second planarization layer 117 is configured to be smaller than the thickness of the plurality of light emitting diodes LED so that an upper portion of the plurality of light emitting diodes LED may be disposed at the outside of the second planarization layer 117. For example, the emission layers 122, 132, and 142 and the p-type semiconductor layers 123, 133, and 143 of the plurality of light emitting diodes LED may be disposed above the top surface of the second planarization layer 117. At least a part of the n-type semiconductor layers 121, 131, and 142 of the plurality of light emitting diodes LED may be covered by the second planarization layer 117.

In the present disclosure, it is described that the second planarization layer 117 has a thickness smaller than that of the n-type semiconductor layers 121, 131, and 141 of the plurality of light emitting diodes LED from the beginning. However, the thickness of the second planarization layer 117 may be adjusted by performing an ashing process.

Next, the first connection electrode CE1 may be formed on the second planarization layer 117. A conductive material layer is formed on the entire surface of the substrate 110 and patterned to form the first connection electrode CE1.

In the meantime, as illustrated in FIG. 3, the n-type semiconductor layers 121, 131, and 141 may be aligned in various directions. For example, as illustrated in FIG. 3, the n-type semiconductor layers 121, 131, and 141 may be aligned along a row direction in one pixel PX, the n-type semiconductor layers 121, 131, and 141 may be aligned along a column direction in an adjacent pixel PX, and the n-type semiconductor layers 121, 131, and 141 may be aligned along a diagonal direction in another adjacent pixel PX. In this case, it may be difficult to connect the plurality of light emitting diodes LED randomly disposed and the first connection electrode CE1 and it may be vulnerable to a short defect, etc. In contrast, in the display device 100 according to the exemplary embodiment of the present disclosure, the first connection electrode CE1 is disposed so as to enclose the side surface of the plurality of light emitting diodes LED. Therefore, the first connection electrode CE1 and the light emitting diode LED may be easily electrically connected without being limited to the alignment direction of the light emitting diode LED.

Next, referring to FIG. 11H, the third planarization layer 118 is formed on the first connection electrode CE1 and the second planarization layer 117. The third planarization layer 118 may be formed to cover the second planarization layer 117, the emission layers 122, 132, and 142 and the p-type semiconductor layers 123, 133, and 143 of the plurality of light emitting diodes LED.

The ashing process is performed on the third planarization layer 118 to totally reduce the thickness of the third planarization layer 118 and expose the p-type electrodes 125, 135, and 145 of the plurality of light emitting diodes LED from the third planarization layer 118.

Finally, the second connection electrode CE2 disposed so as to correspond to the p-type semiconductor layers 123, 133, and 143 is formed on the third planarization layer 118. The second connection electrode CE2 may be electrically connected to the power line VDD through a fourth contact hole CH4 formed in the third planarization layer 118. The second connection electrode CE2 is in contact with top surfaces of the p-type electrodes 125, 135, and 145 exposed from the third planarization layer 118 to be electrically connected to the p-type electrodes 125, 135, and 145 and the p-type semiconductor layers 123, 133, and 143. Accordingly, only the p-type electrodes 125, 135, and 145 on the p-type semiconductor layers 123, 133, and 143 of the plurality of light emitting diodes LED may be exposed to the outside by the ashing process. The second connection electrode CE2 is formed by forming and patterning a metal layer on the entire surface of the substrate 110 on the second planarization layer 117 to easily electrically connect the second connection electrode CE2 to the p-type semiconductor layers 123, 133, and 143 and the p-type electrodes 125, 135, and 145.

Accordingly, in the display device 100 according to the exemplary embodiment of the present disclosure and a method of manufacturing the display device 100, the plurality of light emitting diodes LED is self-assembled on the assembling substrate 200 with an arrangement corresponding to the plurality of sub pixels SP. Thereafter, the plurality of light emitting diodes LED on the assembling substrate 1000 may be transferred to the display panel PN using the donor 2000. When the light emitting diode LED is self-assembled using the electric field, a process of transferring the plurality of light emitting diodes LED from the wafer onto the donor 2000 by aligning the plurality of light emitting diodes LED so as to correspond to the interval of the plurality of sub pixels SP may be omitted. Further, the light emitting diode LED may be easily self-assembled in a correct position using the electric field and the plurality of openings OLH to minimize an alignment error. Accordingly, the plurality of light emitting diodes LED is self-assembled using the assembling substrate 1000 in an arrangement corresponding to the sub pixel SP and is transferred onto the display panel PN as it is. Accordingly, the alignment error of the plurality of light emitting diodes LED may be minimized and the transferring process may be simplified.

In the meantime, in the display device 100 according to the exemplary embodiment of the present disclosure and a method of manufacturing the display device 100, the plurality of light emitting diodes LED is not self-assembled on the assembling substrate 1000 with the arrangement on the wafer, but is self-assembled in a random position. Accordingly, it is possible to minimize a wavelength deviation on the wafer from being displayed on the display panel PN as it is.

In the meantime, the luminance characteristic of the plurality of light emitting diodes may be affected by a shape of the light emitting diode. For example, the luminance deviation may be caused according to the shapes of the plurality of electrodes disposed in the plurality of light emitting diodes and the plurality of semiconductor layers. Therefore, when the plurality of light emitting diodes is formed to have an asymmetric shape, the luminance deviation may occur according to the viewing angle. For example, when the plurality of light emitting diodes is formed in an oval shape, a luminance characteristic in the short axis direction of the light emitting diode may be different from a luminance characteristic in the long axis direction.

In the meantime, on the display panel, all the plurality of light emitting diodes may be disposed to be aligned in the same direction. For example, when the plurality of light emitting diodes is formed to have an oval shape, all the long axis directions of the plurality of light emitting diodes may be disposed along one same direction. Therefore, the luminance characteristic in a corresponding direction may be different from the luminance characteristic in the other direction, on the display panel. Therefore, when all the plurality of light emitting diodes is aligned in the same direction, the luminance asymmetric characteristic may be visible in the display device due to the luminance asymmetric characteristic of the plurality of light emitting diodes.

Therefore, in the display device 100 according to the exemplary embodiment of the present disclosure and the method of manufacturing the display device 100, the long axis direction of the plurality of openings OLH is formed in various directions on the assembling substrate 1000. Therefore, the light emitting diode LED may be self-assembled in various directions in accordance with the shape of the plurality of openings OLH and the plurality of light emitting diodes LED aligned in various directions along the plurality of openings OLH is transferred to the display panel PN. Therefore, the plurality of light emitting diodes LED may be aligned on the display panel PN in various directions. Therefore, even though the plurality of light emitting diodes LED is formed in an asymmetric shape, the plurality of light emitting diodes LED is aligned in various directions to mitigate the luminance deviation. Therefore, a color difference and a stain caused by the viewing angle change in the display panel PN may be minimized and a color uniformity may be improved.

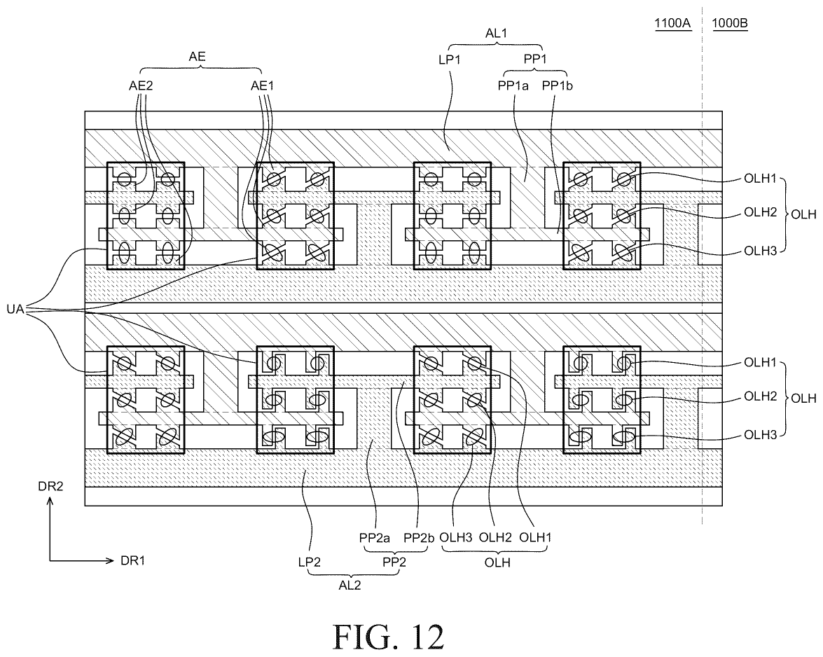

FIG. 12 is a plan view of an assembling substrate according to another exemplary embodiment of the present disclosure. As compared with the assembling substrate 1000 of FIGS. 9 to 11H, only a plurality of assembly electrodes AE of an assembling substrate 1100 of FIG. 12 is different and other configurations are substantially the same so that a redundant description will be omitted.

Referring to FIG. 12, a plurality of assembly electrodes AE is disposed in an assembly area 1100A of the assembling substrate 1100.

Shapes of the plurality of first assembly electrodes AE1 and the plurality of second assembly electrodes AE2 in at least one unit area UA may be different from shapes of the plurality of first assembly electrodes AE1 and the plurality of second assembly electrodes AE2 in an adjacent unit area UA. For example, as illustrated in FIG. 12, a planar shape of each of the plurality of first assembly electrodes AE1 and the plurality of second assembly electrodes AE2 disposed in one unit area UA may be a triangle. Further, a planar shape of each of the plurality of first assembly electrodes AE1 and the plurality of second assembly electrodes AE2 in the adjacent unit area UA may be a rectangle.

Further, when the planar shapes of the plurality of first assembly electrodes AE1 and the plurality of second assembly electrodes AE2 are triangles, in at least one unit area UA, the plurality of first assembly electrodes AE1 and the plurality of second assembly electrodes AE2 may be disposed to be spaced apart from each other along a diagonal direction. Further, when the planar shapes of the plurality of first assembly electrodes AE1 and the plurality of second assembly electrodes AE2 are rectangles, in at least one unit area UA, the plurality of first assembly electrodes AE1 and the plurality of second assembly electrodes AE2 may be disposed to be spaced apart from each other along a column direction or a row direction.

Therefore, an area where each of the plurality of openings OLH overlaps the plurality of first assembly electrodes AE1 and the plurality of second assembly electrodes AE2 may be the same in each of the plurality of unit areas UA.

A long axis direction of the plurality of openings OLH may be formed in various directions in another assembling substrate 1100 of the present disclosure. Therefore, the light emitting diode LED may be self-assembled in accordance with the shapes of the plurality of openings OLH and the plurality of light emitting diodes LED may be aligned on the display panel PN in various directions so that the luminance deviation of the display panel PN may be mitigated.

A long axis direction of the plurality of openings OLH of the plurality of assembly electrodes AE may be formed in various directions in another assembling substrate 1100 of the present disclosure. For example, the shape of the plurality of assembly electrodes AE may be different in every unit area UA. Among the plurality of first assembly electrodes AE1 and the plurality of second assembly electrodes AE2, a first assembly electrode AE1 and a second assembly electrode AE2 which are adjacent to each other may be spaced apart from each other along various directions in every unit area UA. Therefore, an area where each of the plurality of openings OLH overlaps the plurality of first assembly electrodes AE1 and the plurality of second assembly electrodes AE2 may be the same in each of the plurality of unit areas UA. Therefore, when a voltage is applied to the plurality of assembly electrodes AE, all electric fields formed in the opening OLH may be the same and a polarization degree of the light emitting diode LED by the electric field may also be the same. Accordingly, in another assembly substrate 1100 according to the present disclosure, the light emitting diodes LED may be uniformly self-assembled in the plurality of openings OLH to improve an assembly efficiency.

The exemplary embodiments of the present disclosure can also be described as follows:

According to an aspect of the present disclosure, an assembling substrate includes an assembly substrate, a plurality of first assembly lines disposed on the assembly substrate, a plurality of second assembly lines which is disposed on the assembly substrate and is alternately disposed with the plurality of first assembly lines, and an organic layer which is disposed on the plurality of first assembly lines and the plurality of second assembly lines and includes a plurality of openings, and the plurality of openings includes a plurality of first oval openings and a plurality of second oval openings having a different planar shape from the plurality of first oval openings, a plurality of unit areas configured by the plurality of first oval openings and the plurality of second oval openings is defined on the assembly substrate, and in at least one unit area, among the plurality of unit areas, a long axis direction of the plurality of openings is different from a long axis direction of the plurality of openings in an adjacent unit area.

The long axis of the plurality of openings may be disposed in various directions.

A long axis of the plurality of openings may be randomly disposed in the at least one unit area.

Each of the plurality of first assembly lines may include a plurality of first assembly electrodes which is disposed so as to overlap the plurality of openings, each of the plurality of second assembly lines may include a plurality of second assembly electrodes which is disposed so as to overlap the plurality of openings, and an area of the plurality of openings which overlaps the plurality of first assembly electrodes and the plurality of second assembly electrodes in the at least one unit area may be different from an area of the plurality of openings which overlaps the plurality of first assembly electrodes and the plurality of second assembly electrodes in the adjacent unit area.

Each of the plurality of first assembly lines may include a plurality of first assembly electrodes which is disposed so as to overlap the plurality of openings, each of the plurality of second assembly lines may include a plurality of second assembly electrodes which is disposed so as to overlap the plurality of openings, and a shape of the plurality of first assembly electrodes and the plurality of second assembly electrodes in the at least one unit area may be different from a shape of the plurality of first assembly electrodes and the plurality of second assembly electrodes in the adjacent unit area.

An area of the plurality of openings which overlaps the plurality of first assembly electrodes and the plurality of second assembly electrodes may be the same in each of the plurality of unit areas.

In the at least one unit area, a planar shape of the plurality of first assembly electrodes and the plurality of second assembly electrodes may be a triangle and in the adjacent unit area, a planar shape of the plurality of first assembly electrodes and the plurality of second assembly electrodes may be a rectangle.

In the at least one unit area, the plurality of first assembly electrodes and the plurality of second assembly electrodes may be disposed to be spaced apart from each other along a column direction, in the adjacent unit area, the plurality of first assembly electrodes and the plurality of second assembly electrodes may be disposed to be spaced apart from each other along a column direction, and in another adjacent unit area, the plurality of first assembly electrodes and the plurality of second assembly electrodes may be disposed to be spaced apart from each other along a diagonal direction.

The plurality of openings may further include a plurality of circular openings.

According to another aspect of the present disclosure, a method of manufacturing a display device includes self-assembling a plurality of light emitting diodes on an assembling substrate, transferring the plurality of light emitting diodes which is self-assembled on the assembling substrate onto a donor, and transferring the plurality of light emitting diodes of the donor onto an adhesive layer of a display panel, the self-assembling of a plurality of light emitting diodes is a step of forming an electric field by applying a voltage to a plurality of assembly electrodes and self-assembling the plurality of light emitting diodes on the plurality of assembly electrodes with the electric field, the plurality of light emitting diodes includes a plurality of first oval light emitting diodes and a second oval light emitting diodes which has a different planar shape from that of the plurality of first oval light emitting diodes, and the self-assembling of the plurality of light emitting diodes on the assembling substrate includes assembling at least a part of the first oval light emitting diodes in a different direction from the adjacent first oval light emitting diode, and assembling at least a part of the second oval light emitting diodes in a different direction from the adjacent second oval light emitting diode.

The assembling substrate may include a plurality of first openings corresponding to a planar shape of the plurality of first oval light emitting diodes and a plurality of second oval openings corresponding to a planar shape of the plurality of second oval light emitting diode, and the self-assembling of the plurality of light emitting diodes on the assembling substrate may include a step of assembling the plurality of first oval light emitting diodes and the plurality of second oval light emitting diodes in each of the plurality of first oval openings and the plurality of second oval openings.

A long axis of each of the plurality of first oval openings and a long axis of each of the plurality of second oval openings may be disposed in various directions on the assembling substrate and the self-assembling of the plurality of light emitting diodes on the assembling substrate may include a step of assembling the plurality of first oval light emitting diodes and the plurality of second oval light emitting diodes along various long axis directions of each of the plurality of first oval openings and the plurality of second oval openings.

The plurality of light emitting diodes may further include a plurality of circular light emitting diodes, the assembling substrate may further include a plurality of circular openings corresponding to a planar shape of the plurality of circular light emitting diodes, and the self-assembling of the plurality of light emitting diodes on the assembling substrate may include a step of assembling the plurality of circuit light emitting diodes in the plurality of circular openings.

According to yet another aspect of the present disclosure, a display device includes a substrate in which a plurality of pixels including a plurality of sub pixels is defined, and a plurality of light emitting diodes disposed in the plurality of pixels, the plurality of light emitting diodes includes a plurality of oval light emitting diodes, and in at least one pixel among the plurality of pixels, a long axis of the plurality of oval light emitting diodes is disposed in a different direction from a long axis of the plurality of oval light emitting diodes which is disposed in an adjacent pixel.

The plurality of light emitting diodes may include a plurality of first light emitting diodes, a plurality of second light emitting diodes, and a plurality of third light emitting diodes which emit different color light, a planar shape of the plurality of first light emitting diodes may be a circle, a planar shape of the plurality of second light emitting diodes may be an oval, and a planar shape of the plurality of third light emitting diodes may be an oval which is different from the planar shape of the plurality of second light emitting diodes, each of the plurality of light emitting diodes may include an n-type semiconductor layer, an emission layer disposed on the n-type semiconductor layer, a p-type semiconductor layer disposed on the emission layer, a p-type electrode disposed on the p-type semiconductor layer, and an n-type electrode which is disposed on the n-type semiconductor layer and is spaced apart from the emission layer and the p-type semiconductor layer, and side surfaces of the emission layer and the p-type semiconductor layer which face the n-type electrode may be disposed along a circumference of the n-type electrode.

In each of the plurality of light emitting diodes, the n-type electrode may be disposed on one side of the plurality of light emitting diodes and the p-type electrode may be disposed on the other side of the plurality of light emitting diodes.

The n-type electrode may include a curved surface corresponding to a circumference of the n-type semiconductor layer and a side surface formed by a plane which connects the curved surface.

The n-type electrode may be formed by two side surfaces which are curved in one direction.

The n-type electrode may be disposed on both end portions of the plurality of light emitting diodes in each of the plurality of light emitting diodes.

A ratio of a long axis and a short axis of the plurality of second light emitting diodes may be different from a ratio of a long axis and a short axis of the third light emitting diodes.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. An assembling substrate for assembling a plurality of light emitting diodes, comprising:
an assembly substrate;
a plurality of first assembly lines disposed on the assembly substrate;
a plurality of second assembly lines which is disposed on the assembly substrate and is alternately disposed with the plurality of first assembly lines; and
an organic layer which is disposed on the plurality of first assembly lines and the plurality of second assembly lines and includes a plurality of openings, and
wherein the plurality of openings includes a plurality of first oval openings and a plurality of second oval openings having a different planar shape from the plurality of first oval openings, a plurality of unit areas configured by the plurality of first oval openings and the plurality of second oval openings is defined on the assembly substrate, and in at least one unit area, among the plurality of unit areas, a long axis direction of the plurality of openings is different from a long axis direction of the plurality of openings in an adjacent unit area.

2. The assembling substrate according to claim 1, wherein the long axis of the plurality of openings is disposed in various directions.

3. The assembling substrate according to claim 1, wherein a long axis of the plurality of openings is randomly disposed in the at least one unit area.

4. The assembling substrate according to claim 1, wherein each of the plurality of first assembly lines includes a plurality of first assembly electrodes which is disposed so as to overlap the plurality of openings,
each of the plurality of second assembly lines includes a plurality of second assembly electrodes which is disposed so as to overlap the plurality of openings, and
an area of the plurality of openings which overlaps the plurality of first assembly electrodes and the plurality of second assembly electrodes in the at least one unit area is different from an area of the plurality of openings which overlaps the plurality of first assembly electrodes and the plurality of second assembly electrodes in the adjacent unit area.

5. The assembling substrate according to claim 1, wherein each of the plurality of first assembly lines includes a plurality of first assembly electrodes which is disposed so as to overlap the plurality of openings,
each of the plurality of second assembly lines includes a plurality of second assembly electrodes which is disposed so as to overlap the plurality of openings, and
a shape of the plurality of first assembly electrodes and the plurality of second assembly electrodes in the at least one unit area is different from a shape of the plurality of first assembly electrodes and the plurality of second assembly electrodes in the adjacent unit area.

6. The assembling substrate according to claim 5, wherein an area of the plurality of openings which overlaps the plurality of first assembly electrodes and the plurality of second assembly electrodes is the same in each of the plurality of unit areas.

7. The assembling substrate according to claim 6, wherein in the at least one unit area, a planar shape of the plurality of first assembly electrodes and the plurality of second assembly electrodes is a triangle and
in the adjacent unit area, a planar shape of the plurality of first assembly electrodes and the plurality of second assembly electrodes is a rectangle.

8. The assembling substrate according to claim 6, wherein in the at least one unit area, the plurality of first assembly electrodes and the plurality of second assembly electrodes are disposed to be spaced apart from each other along a column direction,
in the adjacent unit area, the plurality of first assembly electrodes and the plurality of second assembly electrodes are disposed to be spaced apart from each other along a column direction, and
in another adjacent unit area, the plurality of first assembly electrodes and the plurality of second assembly electrodes are disposed to be spaced apart from each other along a diagonal direction.

9. The assembling substrate according to claim 1, wherein the plurality of openings further includes a plurality of circular openings.

10. A method of manufacturing a display device, comprising:
self-assembling a plurality of light emitting diodes on an assembling substrate;
transferring the plurality of light emitting diodes which is self-assembled on the assembling substrate onto a donor; and
transferring the plurality of light emitting diodes of the donor onto an adhesive layer of a display panel,
wherein the self-assembling of a plurality of light emitting diodes is a step of forming an electric field by applying a voltage to a plurality of assembly electrodes and self-assembling the plurality of light emitting diodes on the plurality of assembly electrodes with the electric field,
the plurality of light emitting diodes includes a plurality of first oval light emitting diodes and a second oval light emitting diodes which has a different planar shape from that of the plurality of first oval light emitting diodes, and
the self-assembling of the plurality of light emitting diodes on the assembling substrate includes:
assembling at least a part of the first oval light emitting diodes in a different direction from the adjacent first oval light emitting diode, and
assembling at least a part of the second oval light emitting diodes in a different direction from the adjacent second oval light emitting diode.

11. The method of manufacturing a display device according to claim 10, wherein the assembling substrate includes a plurality of first openings corresponding to a planar shape of the plurality of first oval light emitting diodes and a plurality of second oval openings corresponding to a planar shape of the plurality of second oval light emitting diode, and
the self-assembling of the plurality of light emitting diodes on the assembling substrate includes:
a step of assembling the plurality of first oval light emitting diodes and the plurality of second oval light emitting diodes in each of the plurality of first oval openings and the plurality of second oval openings.

12. The method of manufacturing a display device according to claim 11, wherein a long axis of each of the plurality of first oval openings and a long axis of each of the plurality of second oval openings are disposed in various directions on the assembling substrate and
the self-assembling of the plurality of light emitting diodes on the assembling substrate includes:
a step of assembling the plurality of first oval light emitting diodes and the plurality of second oval light emitting diodes along various long axis directions of each of the plurality of first oval openings and the plurality of second oval openings.

13. The method of manufacturing a display device according to claim 11, wherein the plurality of light emitting diodes further includes a plurality of circular light emitting diodes,
the assembling substrate further includes a plurality of circular openings corresponding to a planar shape of the plurality of circular light emitting diodes, and
the self-assembling of the plurality of light emitting diodes on the assembling substrate includes:
a step of assembling the plurality of circuit light emitting diodes in the plurality of circular openings.

14. A display device, comprising:
a substrate in which a plurality of pixels including a plurality of sub pixels is defined; and
a plurality of light emitting diodes disposed in the plurality of pixels,
wherein the plurality of light emitting diodes includes a plurality of oval light emitting diodes, and
in at least one pixel among the plurality of pixels, a long axis of the plurality of oval light emitting diodes is disposed in a different direction from a long axis of the plurality of oval light emitting diodes which is disposed in an adjacent pixel.

15. The display device according to claim 14, wherein the plurality of light emitting diodes includes a plurality of first light emitting diodes, a plurality of second light emitting diodes, and a plurality of third light emitting diodes which emit different color light,
a planar shape of the plurality of first light emitting diodes is a circle, a planar shape of the plurality of second light emitting diodes is an oval, and a planar shape of the plurality of third light emitting diodes is an oval which is different from the planar shape of the plurality of second light emitting diodes,
each of the plurality of light emitting diodes includes:
an n-type semiconductor layer;
an emission layer disposed on the n-type semiconductor layer;
a p-type semiconductor layer disposed on the emission layer;
a p-type electrode disposed on the p-type semiconductor layer; and
an n-type electrode which is disposed on the n-type semiconductor layer and is spaced apart from the emission layer and the p-type semiconductor layer, and
side surfaces of the emission layer and the p-type semiconductor layer which face the n-type electrode are disposed along a circumference of the n-type electrode.

16. The display device according to claim 15, wherein in each of the plurality of light emitting diodes, the n-type electrode is disposed on one side of the plurality of light emitting diodes and the p-type electrode is disposed on the other side of the plurality of light emitting diodes.

17. The display device according to claim 16, wherein the n-type electrode includes a curved surface corresponding to a circumference of the n-type semiconductor layer and a side surface formed by a plane which connects the curved surface.

18. The display device according to claim 16, wherein the n-type electrode is formed by two side surfaces which are curved in one direction.

19. The display device according to claim 16, wherein the n-type electrode is disposed on both end portions of the plurality of light emitting diodes in each of the plurality of light emitting diodes.

20. The display device according to claim 15, wherein a ratio of a long axis and a short axis of the plurality of second light emitting diodes is different from a ratio of a long axis and a short axis of the third light emitting diodes.
